(19) United States
(12) Patent Application Publication
(10) Pub. No.: US 2006/0207642 A1
(43) Pub. Date: Sep. 21, 2006

(54) Method of manufacturing thermoelectric transducer, thermoelectric transducer, and method for forming corrugated fin used for the same

(75) Inventors: Shizuo Maruo, Okazaki-city (JP); Yukinori Hatano, Okazaki-city (JP); Fumiaki Nakamura, Kariya-city (JP); Akio Matsuoka, Takahama-city (JP); Isao Kuroyanagi, Anjo-city (JP); Takashi Yamamoto, Okazaki-city (JP); Yasuhiko Niimi, Handa-city (JP)

Correspondence Address: HARNESS, DICKEY & PIERCE, P.L.C., P.O. BOX 828, BLOOMFIELD HILLS, MI, 48303, US

(73) Assignee: DENSO Corporation, Kariya-city (JP)

(21) Appl. No.: 11/396,127

(22) Filed: Mar. 31, 2006

Related U.S. Application Data
(63) Continuation-in-part of application No. 11/288,459, filed on Nov. 29, 2005.

(30) Foreign Application Priority Data
Nov. 30, 2004 (JP) 2004-347101
Aug. 2, 2005 (JP) 2005-224630
Apr. 1, 2005 (JP) 2005-106854

(51) Int. Cl. H01L 35/34; H01L 35/28

(52) U.S. Cl. 136/201; 136/204

(57) ABSTRACT

A thermoelectric transducer includes a group of thermoelectric devices having a plurality of P-type thermoelectric devices and a plurality of N-type thermoelectric devices alternately arranged on a thermoelectric device substrate, electrode members for electrically connecting the adjacent P-type and N-type thermoelectric devices in series, and heat exchanging members including electrode portions connected to the electrode members. In the thermoelectric transducer, at least a plurality of electrode portions and a plurality of heat exchanging portions are formed continuously in a corrugated shape to couple the plurality of electrode members to each other along at least the group of thermoelectric devices, and the adjacent heat exchanging members are provided to be electrically insulated from each other. Accordingly, the thermoelectric transducer can be easily formed.

### CROSS REFERENCE TO RELATED APPLICATION

This application is a continuation in part application of U.S. patent application Ser. No. 11/288,459, filed on Nov. 29, 2005, and is based on Japanese Patent Applications No. 2004-347101 filed on Nov. 30, 2004, No. 2005-224630 filed on Aug. 2, 2005, and No. 2005-106854 filed on Apr. 1, 2005, the contents of which are incorporated herein by reference in its entirety.

### BACKGROUND OF THE INVENTION

1. Field of the Invention

The present invention relates to a thermoelectric transducer that has a series circuit including N-type thermoelectric devices and P-type thermoelectric devices and absorbs or radiates heat when a DC current is passed through the series circuit. The present invention further relates to a method for manufacturing a thermoelectric transducer, and a method for forming a corrugated fin used for the thermoelectric transducer.

2. Description of the Related Art

As one of conventional thermoelectric transducers, there is proposed a thermoelectric transducer that has N-type thermoelectric devices and P-type thermoelectric devices alternately arranged in the shape of a plane. In this thermoelectric transducer, the respective thermoelectric devices have one-side electrode members mounted on their one-side surfaces and have other-side electrode members mounted on their other-side surfaces, thereby all thermoelectric devices are connected to each other in series (refer to JP-A-2003-124531 corresponding to U.S. Pat. No. 6,815,814). In the thermoelectric devices of this type, heat exchanging members for absorbing or radiating heat transmitted from the one-side electrode members and the other-side electrode members are integral with the one-side electrode members and the other-side electrode members.

As a method for forming a heat exchanging member, a technology for forming a corrugated fin used for a heat exchanger of a radiator for a vehicle or the like is disclosed in JP-A-8-229615 (corresponding to U.S. Pat. No. 5,679,106). According to the technology, a corrugated fin is continuously formed by bending a fin material of a sheet plate and by partially cutting and raising the fin material to form louvers.

In the thermoelectric transducer in the related art, heat exchange members are integrally formed with the electrode members and hence a large scale forming apparatus is required. This increases cost in the forming of the electrode members and heat exchange members.

A thick corrugated fin may be used for a thermoelectric transducer having N-type thermoelectric devices and P-type thermoelectric devices alternately arranged in the shape of a plane, as disclosed in JP-A-2003-124531. However, in this case, in order to electrically insulate adjacent electrode members and heat exchanger members from each other, the corrugated fin to be used as the heat exchange members needs to be cut at coupling portions for coupling electrodes after the corrugated fin is bonded to the electrode members.

Cutting by using a cutting jig such as a laser and a cutter, punching, or the like is considered as a cutting method for cutting the coupling portions of the corrugated fin. When the coupling portions are cut and separated from each other to secure electric insulation in the divided portions of the coupling portions, any of the cutting methods produces cutting dust and hence raises a possibility that the cutting dust might enter the thermoelectric transducer to cause faulty electric insulation.

Moreover, when the corrugated fin is cut by a cutting jig or the like, because the thickness of the corrugated fin is thick, load required to cut the corrugated fin becomes large and hence a cutting force applied to the corrugated fin increases. When the cutting force increases, there is a possibility that the corrugated fin will be deformed to make an effect on a thermoelectric device that is comparatively brittle.

### SUMMARY OF THE INVENTION

In view of the foregoing problems, it is an object of the present invention to provide a thermoelectric transducer, in which a plurality of heat exchanging members can be formed continuously.

It is another object of the present invention to provide a thermoelectric transducer and a method of manufacturing a thermoelectric transducer with reduced steps and man-hours necessary for manufacturing.

It is another object of the present invention to provide a thermoelectric transducer, a method of manufacturing a thermoelectric transducer and a method of forming a corrugated fin for the thermoelectric transducer, which are possible to cut a coupling portion of a continuously formed heat exchanging portions by a small cutting force without producing cutting dust.

It is another object of the present invention to provide a thermoelectric transducer, a method of manufacturing a thermoelectric transducer and a method of forming a corrugated fin for the thermoelectric transducer, which can improve insulating performance between adjacent heat exchanging portions continuously formed.

According to an aspect of the present invention, a thermoelectric transducer includes a thermoelectric device substrate, a group of thermoelectric devices including a plurality of P-type thermoelectric devices and a plurality of N-type thermoelectric devices alternately arranged on the thermoelectric device substrate, electrode members made of a conductive material and for electrically connecting the P-type thermoelectric devices and the N-type thermoelectric devices arranged adjacent to each other on the thermoelectric device substrate, and heat exchanging members having electrode portions connected to the electrode members to transmit heat thereto and heat exchanging portions for absorbing and radiating the heat transmitted from the electrode portions. In the thermoelectric transducer, the adjacent P-type and N-type thermoelectric devices are connected to each other in series via the electrode members. Further, among the electrode portions and the heat exchanging portions in the heat exchanging members, at least a plurality of electrode portions and a plurality of heat exchanging portions are formed continuously in a corrugated shape to couple the plurality of electrode members to each other along at least the group of thermoelectric devices, and the adjacent heat exchanging members are provided to be electrically insulated from each other.

Because a plurality of heat exchanging members are formed continuously in a corrugated shape and are bonded to one end surfaces of the electrode members, it is possible to effectively decrease the number of steps required to form and assemble the heat exchanging members.

Further, because the heat exchanging members are electrically insulated from each other by cutting the coupling portions, it is possible to connect the heat exchanging members to the thermoelectric devices in series via the electrode members.

For example, in the heat exchanging member, a plurality of adjacent heat exchanging portions are coupled continuously in a corrugated shape via coupling portions, and the adjacent heat exchanging portions are electrically insulated from each other by cutting the coupling portions. In this case, end portions of the heat exchanging portions, from which the coupling portions are cut off, can be fixed by using a fixing member having a flat plate shape and made of an insulating material. Alternatively, the electrode portions of the heat exchanging member can be fitted into a plurality of fitting holes formed at intervals in an insulating substrate.

Furthermore, the plurality of the heat exchanging portions can be provided continuously in the corrugated shape via coupling portions each having an arch portion, the adjacent heat exchanging portions can be electrically insulated from each other by cutting the coupling portions, and a corner of the arch portion of the cut coupling portion can be provided with a cut-raised portion. Therefore, it is possible to form a cut-raised portion capable of guiding, for example, a cutting blade used for cutting the coupling portion on the notch groove having a thin thickness of the coupling portion. As a result, it is possible to cut the coupling portion by a small cutting force without producing cutting dust.

For example, the arch portion of the cut coupling portion can be cut and raised in such a way as to have a width Wf larger than a width Wa of the heat exchanging portion.

According to another aspect of the present invention, a thermoelectric transducer includes a thermoelectric device assembly located between a pair of heat exchanging device assemblies. The thermoelectric device assembly includes a plurality of P-type thermoelectric devices, a plurality of N-type thermoelectric devices, and a first holding plate for holding these plurality of thermoelectric devices. Furthermore, each of the heat exchanging device assemblies includes a plurality of heat exchanging devices provided in correspondence with the plurality of thermoelectric devices, and a second holding plate for holding these plurality of heat exchanging devices. Here, the plurality of heat exchanging devices are held in an arrangement corresponding with a predetermined arrangement of the thermoelectric devices, and a fixing plate is provided for fixing the heat exchanging devices. In the thermoelectric transducer, the respective thermoelectric devices are connected electrically to the respective heat exchanging devices in a state where the thermoelectric device assembly is located between the pair of heat exchanging device assemblies, and each of the heat exchanging devices has an electrode portion connected to the thermoelectric device to transmit heat, and a heat exchanging portion for exchanging heat transmitted from the electrode portion. Furthermore, the heat exchanging device assembly has a first portion close to a connection portion of the electrode portion, which is held by the second holding plate, and a second portion opposite to the electrode portion, which is fixed to the fixing plate. Accordingly, it can prevent the heat exchanging device from being removed from the fixing plate when the heat exchanging device assembly is formed. In addition, adjacent heat exchanging devices in each heat exchanging device assembly are electrically insulated from each other. Therefore, it can prevent adjacent heat exchanging devices from being electrically connected to each other.

For example, the thermoelectric device assembly further includes a plurality of electrode devices for electrically connecting the plurality of P-type thermoelectric devices directly to the plurality of N-type thermoelectric devices. In this case, the electrode portions of the heat exchanging devices are connected to the thermoelectric devices via the electrode devices to transmit heat.

The heat exchanging portion of the heat exchanging device can extend outward from the electrode portion to have an extended end portion. In this case, the extended end portion of the heat exchanging portion is fixed to a fixing portion of the fixing plate to generate a frictional force between the extended end portion and the fixing portion of the fixing plate.

Further, in each of the heat exchanging device assemblies, the plurality of heat exchanging devices can be coupled continuously in a corrugated shape via coupling portions, and the adjacent heat exchanging portions can be electrically insulated from each other by cutting the coupling portion.

Furthermore, the end portion of the heat exchanging device, opposite to the electrode portion, can be gradually expanded or narrowed from the electrode portion toward a tip end of the end portion, to be fixed to the fixing plate.

When the end portion of the heat exchanging device, opposite to the electrode portion is gradually expanded toward the tip end, the fixing plate is provided with a fixing portion formed adjacent to the coupling portion before being cut. When the end portion of the heat exchanging device, opposite to the electrode portion is gradually narrowed toward the tip end, the fixing plate is provided with a fixing portion formed at a portion opposite to the electrode portion.

According to another aspect of the present invention, a method of manufacturing a thermoelectric transducer includes a step of forming a plurality of heat exchanging members, each of which includes a first heat exchanging portion, an electrode portion, a second heat exchanging portion and a coupling portion in this order, continuously in a corrugated shape by using a conductive material; a step of forming a thermoelectric device substrate on which a plurality of P-type thermoelectric devices and a plurality of N-type thermoelectric devices are alternately arranged substantially in a lattice pattern to arrange a group of thermoelectric devices; a step of placing electrode members on end surfaces of the P-type thermoelectric devices and the N-type thermoelectric devices, which are arranged adjacent to each other on the thermoelectric device substrate, and then bonding the electrode members to the P-type thermoelectric devices and the electrode members to the N-type thermoelectric devices; a step of placing a plurality of rows of the electrode portions of the plurality of heat exchanging members formed in the corrugated shape in the step of forming the heat exchanging members on one end surfaces of the electrode members along at least the group of thermoelectric devices, and then bonding the electrode members to the electrode portions; and a step of cutting the coupling portions formed between the adjacent heat exchanging portions of the plurality of heat exchanging members having their electrode portions bonded to the electrode members in the step of bonding the heat exchanging member, to thereby electrically insulate the heat exchanging members from each other. Accordingly, the thermoelectric transducer can be easily formed.

Furthermore, it is possible to form a cut-raised portion capable of guiding a cutting blade on a notch groove having a thin thickness of the coupling portion. As a result, it is possible to cut the coupling portion by a small cutting force without producing cutting dust.

The method can be further provided with a provisionally assembling step in which the electrode portions are fitted or pressed in fitting holes formed at intervals in an insulating substrate shaped like a flat plate and made of an insulating material after the step of forming the heat exchanging members. Furthermore, in the step of forming the heat exchanging members, a plurality of the heat exchanging members can be formed in a corrugated shape by roller process. Therefore, the number of the steps for manufacturing the thermoelectric transducer can be reduced.

According to another aspect of the present invention, there is provided with a method of manufacturing a corrugated fin for forming a plurality of heat exchanging members each of which includes a heat exchanging portion, an electrode portion, a heat exchanging portion, and a coupling portion in this order, continuously in a corrugated shape by using a fin material shaped like a belt and made of a conductive material. This method includes a step of forming a notch groove on a coupling portion in a direction in which a coupling portion is to be cut, a step of bending the fin material at portions between the electrode portion, the heat exchanging portion, and the coupling portion to form them in the corrugated shape, a step of forming a louver in the heat exchanging portion between a crest and a trough in the corrugated shape, and a step of forming a cut-raised portion for guiding a cutting blade from a starting point at an end of the notch groove. Therefore, the cutting can be easily performed by using the cutting blade guided through the cut-raised portion.

Furthermore, according another aspect of the present invention, a method of manufacturing a thermoelectric transducer includes: a step of forming a plurality of heat exchanging devices each of which includes a first heat exchanging portion, an electrode portion, a second heat exchanging portion and a coupling portion in this order, continuously in a corrugated shape by using a conductive material; a step of forming a thermoelectric device assembly in which a plurality of P-type thermoelectric devices and a plurality of N-type thermoelectric devices are arranged in a predetermined arrangement to be held by a first holding plate; a step of forming a pair of heat exchanging device assemblies each of which includes the heat exchanging devices provided in correspondence with the plurality of thermoelectric devices, and a second holding plate for holding these plurality of heat exchanging devices, the plurality of heat exchanging devices being held in an arrangement corresponding with the predetermined arrangement of the thermoelectric devices; and a step of connecting the respective thermoelectric devices to the respective heat exchanging devices in a state where the thermoelectric device assembly is located between the pair of heat exchanging device assemblies; a step of cutting the coupling portion formed between each of adjacent heat exchanging portions to have a cut portion; and a step of fixing the cut portion to a fixing plate. Therefore, the thermoelectric transducer can be easily formed with reduced manufacturing steps.

For example, the step of forming the thermoelectric device assembly includes a step of forming a plurality of electrode devices for electrically connecting the P-type thermoelectric devices and the N-type thermoelectric devices. In this case, in the connecting step, electrode portions of the heat exchanging devices are connected to the thermoelectric devices via the electrode devices.

Furthermore, the cutting step can be performed after the coupling portion is inserted into a fixing portion of the fixing plate.

### BRIEF DESCRIPTION OF THE DRAWINGS

The above and other objects, features and advantages of the present invention will become more apparent from the following detailed description of preferred embodiments made with reference to the accompanying drawings, in which:

FIG. 1 is a plan view showing a part of a thermoelectric transducer in a first embodiment of the present invention;

FIG. 2 is a sectional view taken on the line II-II shown in FIG. 1;

FIG. 3 is a sectional view taken on the line III-III shown in FIG. 2;

FIG. 4 is an exploded schematic view showing a structure of the thermoelectric transducer in the first embodiment of the present invention;

FIG. 5 is a plan view showing a structure of a second insulating substrate in the first embodiment of the present invention;

FIG. 6A and FIG. 6B are sectional views taken on the line VI-VI shown in FIG. 1, before and after cutting;

FIG. 7 is a diagram showing the step of cutting in the first embodiment of the present invention;

FIG. 8 is a schematic sectional view showing a structure of a thermoelectric transducer in a second embodiment of the present invention;

FIG. 9A is a plan view showing a first fixing member in the second embodiment of the present invention, and FIG. 9B is a sectional view taken on the line IXB-IXB shown in FIG. 9A;

FIG. 10 is a schematic sectional view showing a structure of a thermoelectric transducer in a modification of the second embodiment of the present invention;

FIG. 11 is a schematic diagram showing the step of cutting in a modification of the present invention;

FIG. 12 is a schematic diagram showing the step of cutting in a modification of the present invention;

FIG. 13 is a schematic sectional view showing a thermoelectric transducer according to a third embodiment of the present invention;

FIG. 14 is a plan view showing the thermoelectric transducer in FIG. 13;

FIG. 15 is a sectional view taken on the line XV-XV in FIG. 13;

FIG. 16 is a schematic sectional view taken on the line XVI-XVI in FIG. 14;

FIG. 17 is a disassembled view showing the structure of the thermoelectric transducer in FIG. 13;

FIG. 18 is a disassembled perspective view showing a manufacturing process of the thermoelectric transducer in FIG. 13;

FIG. 19A is a plan view when viewed from a direction in which a cutting blade is moved and FIG. 19B is a side view of FIG. 19A;

FIG. 20 is a perspective view showing the step of cutting in the manufacturing process of the thermoelectric transducer in FIG. 13;

FIG. 21 is a schematic diagram showing the step of cutting in FIG. 20 when a moving cutting blade is viewed from the tip of the blade;

FIG. 22 is a diagram showing the process of a method for forming a corrugated fin for the thermoelectric transducer in FIG. 13;

FIG. 23 is a diagram showing the process of a method for forming a corrugated fin according to a modification of the third embodiment of the present invention;

FIG. 24 is a plan view showing a main portion of a thermoelectric transducer in a fourth embodiment of the present invention;

FIG. 25 is a cross-sectional view taken on a line XXV-XXV in FIG. 24;

FIG. 26 is a cross-sectional view taken on a line XXVI-XXVI in FIG. 25;

FIG. 27 is a cross-sectional view taken on a line XXVII-XXVII in FIG. 25;

FIG. 28 is a disassembled schematic view showing the thermoelectric transducer in the fourth embodiment of the present invention;

FIG. 29 is a plan view showing the shape of a second holding plate in the fourth embodiment of the present invention;

FIGS. 30A and 30B are cross-sectional views taken on a line XXX-XXX in FIG. 24;

FIGS. 31A and 31B are diagrams showing a method for manufacturing a heat exchanging member in the fourth embodiment of the present invention;

FIG. 32 is a longitudinal sectional view showing a shape of the heat exchanging member after fitting in a fifth embodiment of the present invention;

FIGS. 33A to 33F are schematic views showing the shape of a heat exchanging member before and after fitting in the fifth embodiment of the present invention;

FIGS. 34A to 34F are schematic views showing the shape of a heat exchanging member before and after fitting in a modification of the fifth embodiment of the present invention; and

FIG. 35 is a schematic view showing a thermoelectric transducer in a modification of the present invention.

### DETAILED DESCRIPTION OF THE PREFERRED EMBODIMENTS

### First Embodiment

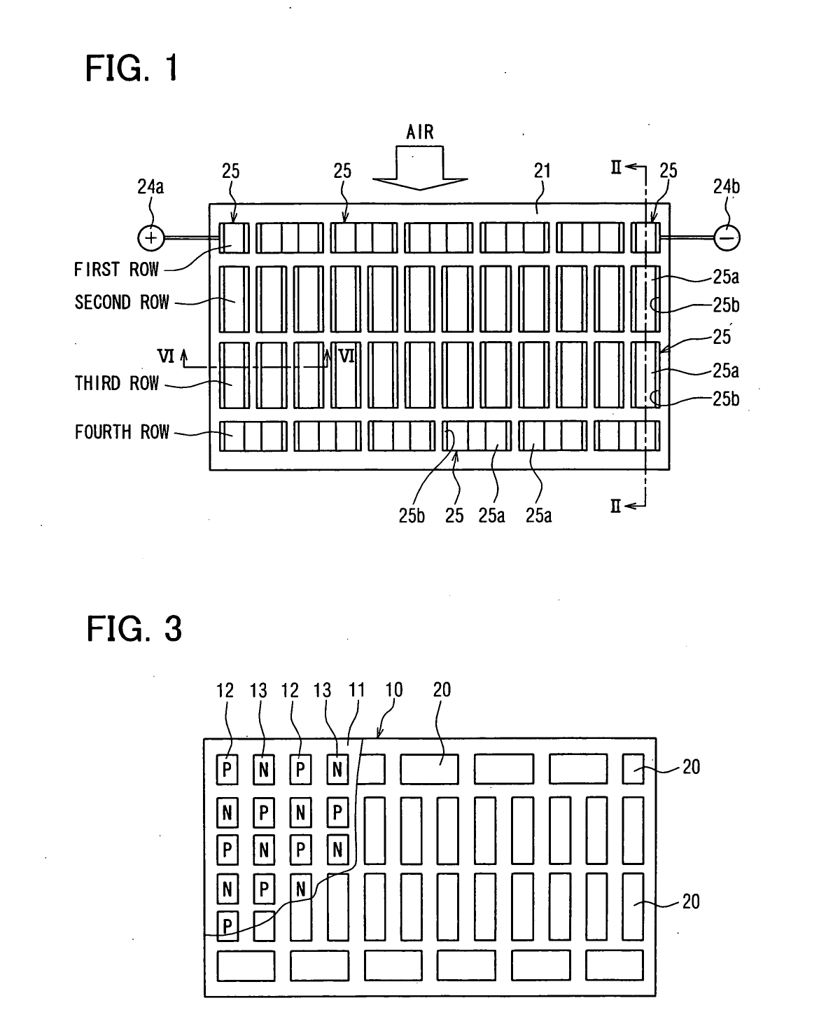

The first embodiment of the present invention will be described with reference to FIGS. 1-7. FIG. 1 shows a part of a thermoelectric transducer in the first embodiment.

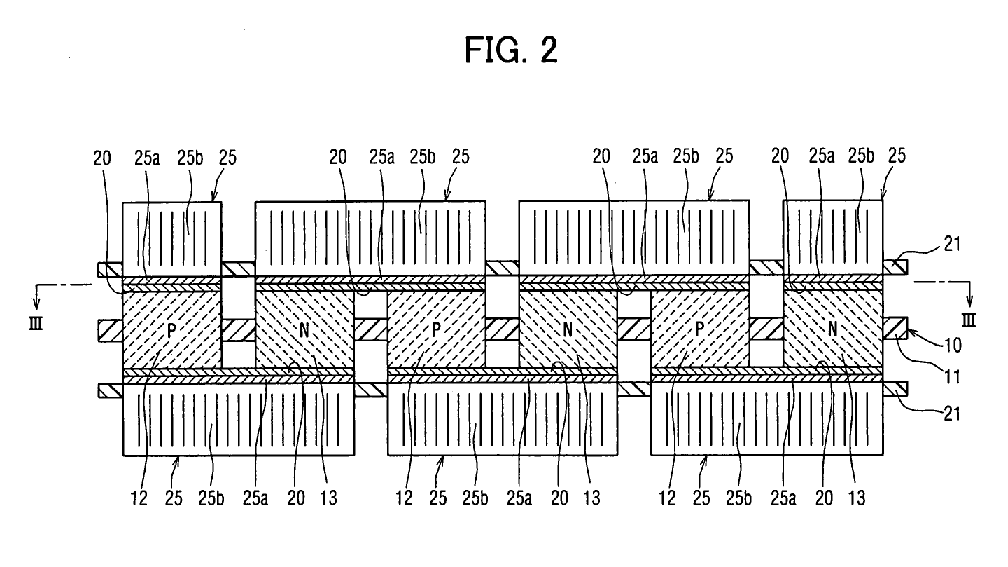

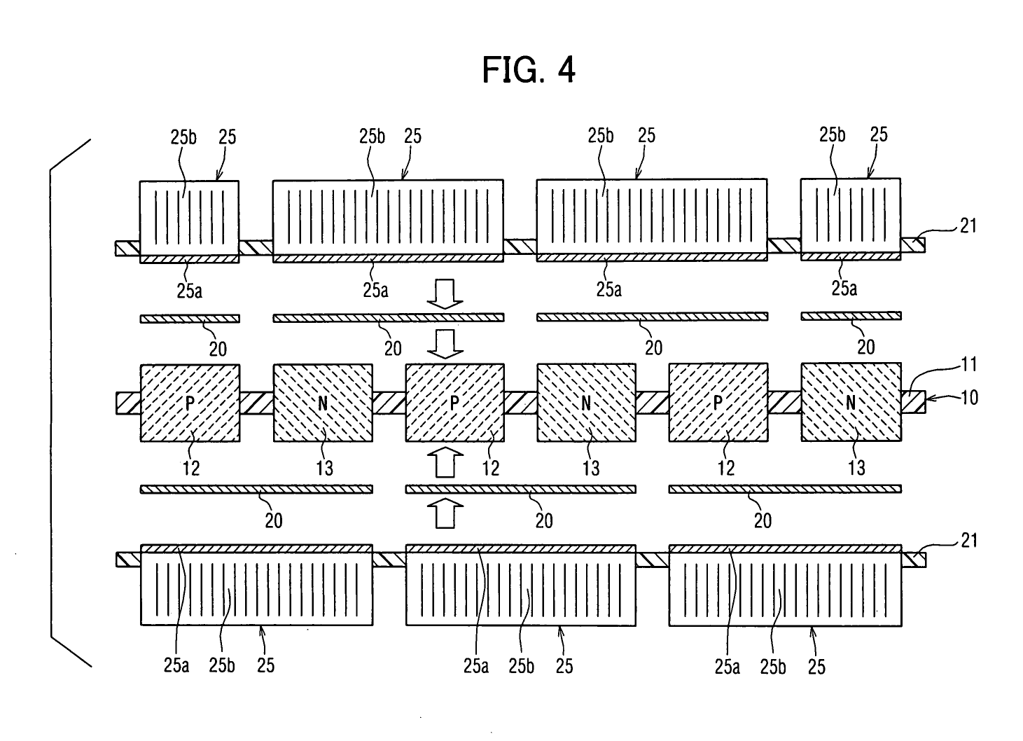

The thermoelectric transducer of this embodiment, as shown in FIG. 2 and FIG. 4, is constructed of a thermoelectric device substrate 10 having a plurality of P-type thermoelectric devices 12 and a plurality of N-type thermoelectric devices 13 arranged in lines thereon, electrode members 20 for electrically connecting the adjacent thermoelectric devices 12, 13, and heat exchanging members 25 connected to the electrode members 20 in such a way as to transmit heat.

As shown in FIG. 3, the thermoelectric device substrate 10 is formed by arranging a group of thermoelectric devices including a plurality of P-type thermoelectric devices 12 and a plurality of N-type thermoelectric devices 13 alternately in lines on a first insulating substrate 11 made of a plate-shaped insulating material (for example, glass epoxy, PPS resin, LCP resin, or PET resin), thereby integrating them into one piece.

The P-type thermoelectric device 12 is an extremely small component constructed of a P-type semiconductor made of Bi—Te based compound, and the N-type thermoelectric device 13 is an extremely small component constructed of an N-type semiconductor made of Bi—Te based compound. The thermoelectric device substrate 10 is integrally formed in such a way that the P-type thermoelectric devices 12 and the N-type thermoelectric devices 13 are arranged in a lattice pattern on a first insulating substrate 11. At this time, the P-type thermoelectric devices 12 and the N-type thermoelectric devices 13 are formed in such a way as to protrude their top end surfaces and bottom surfaces from the first insulating substrate 11.

The electrode member 20 is an electrode formed of plate-shaped conductive metal such as copper and for electrically connecting the adjacent P-type thermoelectric devices 12 and N-type thermoelectric devices 13 among the group of thermoelectric devices arranged on the thermoelectric device substrate 10. In other words, a plurality of electrode members 20 are arranged on both ends of the adjacent thermoelectric devices 12, 13 in such a way that the thermoelectric devices 12, 13 are connected in series via the electrode members 20.

In this regard, as to the electrode members 20, as shown in FIG. 3, the electrode members 20 arranged on the top and bottom ends and the electrode members 20 arranged inside them are different from each other in the plane shape but are arranged in such a way that adjacent thermoelectric devices 12, 13 are electrically connected to each other. Here, the electrode members 20 are bonded by solder to the end surfaces of the thermoelectric devices 12, 13, which will be described below in detail.

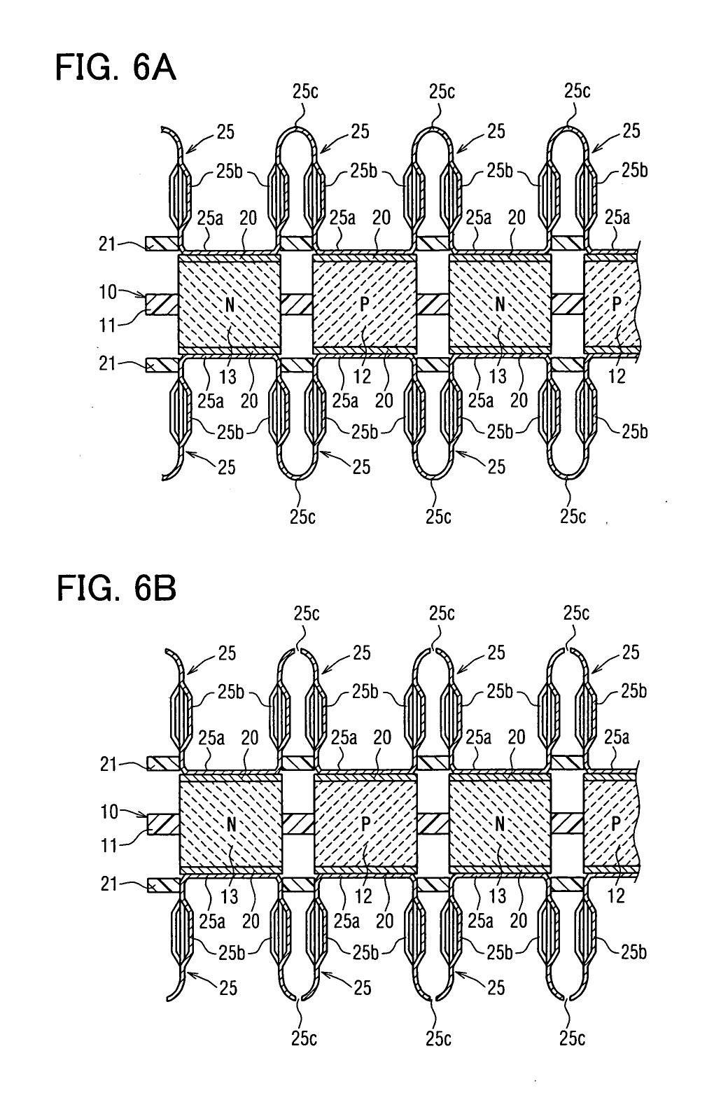

Then, the heat exchanging member 25 is formed of a conductive metal such as copper having a thin thickness (for example, about 0.2 mm) and is formed nearly in the shape of a letter U in section. The heat exchanging member 25 has an electrode portion 25a on the bottom portion and louvers 25b of a heat exchanging portion on a plane extending outward from the electrode portion 25a, as shown in FIG. 6A. These louvers 25b are fins for absorbing or radiating heat transmitted from the electrode portion 25a and are integrally formed with the electrode portion 25a by cutting and raising, or the like.

The plural heat exchanging members 25 are constructed such that portions between adjacent louvers 25b are connected to each other via coupling portions 25c. In other words, in this embodiment, the heat exchanging members 25 are not formed as single parts, but a plurality of heat exchanging members 25 are formed in a collective manner and the electrode portions 25a are bonded to the electrode member 20 and then the coupling portions 25c are cut in such a way as to electrically insulate the heat exchanging members 25 from each other.

Specifically, a plurality of heat exchanging members 25 are formed continuously in a corrugated shape via the coupling portions 25c between the adjacent louvers 25b at least along a group of thermoelectric devices among the thermoelectric devices 12, 13 arranged in a lattice pattern on the thermoelectric device substrate 10. That is, as shown in FIG. 1, a plurality of heat exchanging members 25 are connected to each other via the coupling portions 25c for each row from the first row to the fourth row.

In this embodiment, the heat exchanging members 25 each having the electrode portion 25a and the louvers 25b are formed in a corrugated shape. Accordingly, as compared with the case of forming the heat exchanging members 25 as single parts by pressing, the case of forming a plurality of heat exchanging members 25 by roller process is extremely more excellent particularly in the productivity of the step of forming the louvers 25b.

As compared with the case of manufacturing the heat exchanging members 25 by press process using male and female dies, the case of roller process of the heat exchanging members 25, in which material is fed by rollers, thereby being formed into the electrode portions 25a, louvers 25b, and the coupling portions 25c in succession, can reduce cost in the equipment of a forming step. In this embodiment, the heat exchanging member 25 is formed to have the louvers 25b, but may be formed to have the shape of a slit, an offset, or the like.

In this embodiment, as shown in FIG. 1, the heat exchanging members 25 arranged in the first row, the second and third rows, and the fourth row are different in the plane shape but each of them is formed in a corrugated shape. The plurality of heat exchanging members 25 manufactured for each row are so constructed as to be arranged on a second insulating substrate 21 having plate-shaped electrode members 25a made of an insulating material (for example, glass epoxy, PPS resin, LCP resin, or PET resin).

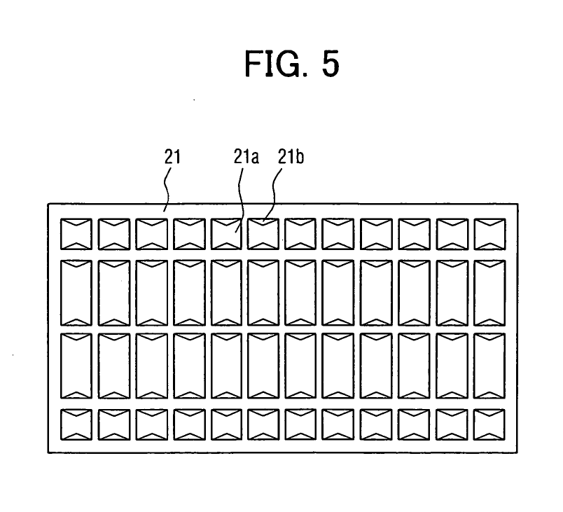

Specifically, as shown in FIG. 5, fitting holes 21a in which the electrode portions 25a are fitted are formed in the second insulating substrate 21, and the electrode portions 25a are fitted into the fitting holes 21a to integrate the heat exchanging members 25 and the second insulating substrate 21 into one piece. Here, a portion denoted by a reference sign 21b is a claw portion which is a protruding claw for preventing the electrode portion 21a from being detached when the electrode portion 21a is fitted into the fitting hole 21a.

Moreover, as shown in FIG. 1, terminals 24a, 24b are provided at the ends of the electrode members 20 arranged on the left and right ends shown in the drawing. The positive terminal of a DC power supply (not shown) is connected to the terminal 24a of these terminals 24a, 24b, and the negative terminal of the DC power supply is connected to the terminal 24b.

Accordingly, as to the electrode members 20 arranged on the upper side of the first insulating member 11, a plurality of electrode members 20 are arranged on the end surfaces of the thermoelectric devices 12, 13 in such a way as to electrically form NP junctions. Further, as to the electrode members 20 arranged on the lower side of the first insulating member 11, a plurality of electrode members 20 are arranged on the end surfaces of the thermoelectric devices 12, 13 in such a way as to electrically form PN junctions.

A DC current applied from the terminal 24a shown in FIG. 1, as shown in FIG. 2, is passed from the upper electrode member 20 at the left end in the drawing through the P-type thermoelectric device 12 and then is passed via the lower electrode member 20 to the N-type thermoelectric device 13 in series and then is passed from this N-type thermoelectric device 13 via the upper electrode member 20 to the P-type thermoelectric device in series. In other words, the electrode members 20 are connected to both end surfaces of the thermoelectric devices 12, 13 in such a way as to pass a DC current through the thermoelectric devices 12, 13 in series.

At this time, by Peltier effect, the lower electrode members 20 for forming the PN junctions are brought into the state of high temperature, and the upper electrode members 20 for forming the NP junctions are brought into the state of low temperature. In short, the louvers 25b arranged on the lower side form the heat-radiating heat exchanging portion of a heat radiating portion, has high temperature transmitted thereto and are cooled by cooling fluid (e.g., air). Furthermore, the louvers 25b arranged on the upper side form the heat-absorbing heat exchanging portion of a heat absorbing portion, and are brought into the state of low temperature to cool fluid to be cooled.

In other words, as shown in FIG. 2, air passages are formed in case members (not shown) on both sides of the thermoelectric device substrate 10 by using the thermoelectric device substrates 10 as partition walls, and air passes through the air passages to exchange heat between the louvers 25b and air. That is, by using the thermoelectric device substrates 10 as partition walls, the lower louvers 25b can heat air and the upper louvers 25b can cool air.

In this embodiment, the positive terminal of the DC power supply is connected to the terminal 24a, and the negative terminal thereof is connected to the terminal 24b to pass the DC current through the terminal 24a. However, the connection is not limited to this, but the positive terminal of the DC power supply may be connected to the terminal 24b, and the negative terminal is connected to the terminal 24a to pass the DC current through the terminal 24b.

However, at this time, the lower heat exchanging members 25 form the heat-absorbing heat exchanging portions and the upper heat exchanging members 25 form the heat-radiating heat exchanging portions.

Next, a method for manufacturing a heat exchanging member 25 of the main part of the present invention and a method for mounting a thermoelectric transducer will be described. First, as to the method for manufacturing a plurality of heat exchanging members 25, the plurality of heat exchanging members 25 are manufactured by roller process. That is, a belt-shaped conductive material is fed through a pair of female and male rollers to form a plurality of heat exchanging members 25 each having the louver 25b, the electrode portion 25a, the louver 25b, and the connecting potion 25c formed in succession continuously in a corrugated shape. This step is referred to as the step of forming a heat exchanging member.

A plurality of P-type thermoelectric devices 12 and a plurality of N-type thermoelectric devices 13 are arranged alternately in a lattice pattern in the holes formed in the first insulating substrate 11, as shown in FIG. 3, so as to integrally construct the thermoelectric device substrate 10. At this time, a mounting apparatus for mounting a semiconductor, an electronic component and the like to a board may be used. This step is referred to as the step of mounting a thermoelectric device.

Then, the electrode members 20 each formed in the shape of a plane are pinched and then, as shown in FIG. 3, are put on the end surfaces of the thermoelectric devices 12, 13 which are arranged adjacently to each other on the thermoelectric device substrate 10. After the plurality of electrode members 20 are put on the end surfaces of the respective thermoelectric devices 12, 13, the thermoelectric devices 12, 13 are bonded by solder to the electrode members 20. This step is referred to as the step of bonding an electrode member.

In this regard, this step of bonding an electrode member is carried out for each surface. That is, when the step of bonding an electrode member is carried out for one surface, the thermoelectric device substrate 10 is turned upside down and the step of bonding an electrode member is carried out for the other surface to bond the other surface. Moreover, when paste solder or the like is previously applied uniformly thinly to the bonding surfaces of the end surfaces of the thermoelectric devices 12, 13 by screen printing and then the step of bonding an electrode member is carried out, the soldering can be easily carried out.

The plurality of heat exchanging members 25 formed in the corrugated shape by the step of forming a heat exchanging member are pinched and the electrode portions 25a are inserted into the fitting holes 21a formed in a second insulating substrate 21 along the group of thermoelectric devices for each row, thereby the plurality of heat exchanging members 25 are constructed integrally with the second insulating substrate 21. This is referred to as the step of provisionally mounting a heat exchanging member. In this regard, also this step of provisionally mounting a heat exchanging member is carried out for each surface. That is, when this step is carried out for one surface, the thermoelectric device substrate 10 is turned upside down and then this step is carried out for the other surface to bond the other surface.

The electrode portions 25a are put on one end surfaces of the electrode members 20 bonded in the above-described step of bonding an electrode member and then the electrode members 20 are bonded by solder to the electrode portions 25a. This step is referred to as the step of bonding a heat exchanging member. Then, the coupling portions 25c formed between the adjacent louvers 25b of the heat exchanging members 25 bonded in the step of bonding a heat exchanging member are cut. This step is referred to as a cutting step.

This cutting step will be described on the basis of FIG. 6A and FIG. 6B. FIG. 6A is a schematic diagram when the above-described step of bonding a heat exchanging member is finished and shows a state where the heat exchanging members 25 are electrically connected to each other via the coupling portions 25c. These coupling portions 25c are cut in the cutting step, as shown in FIG. 6B. With this, the adjacent heat exchanging members 25 are electrically insulated from each other.

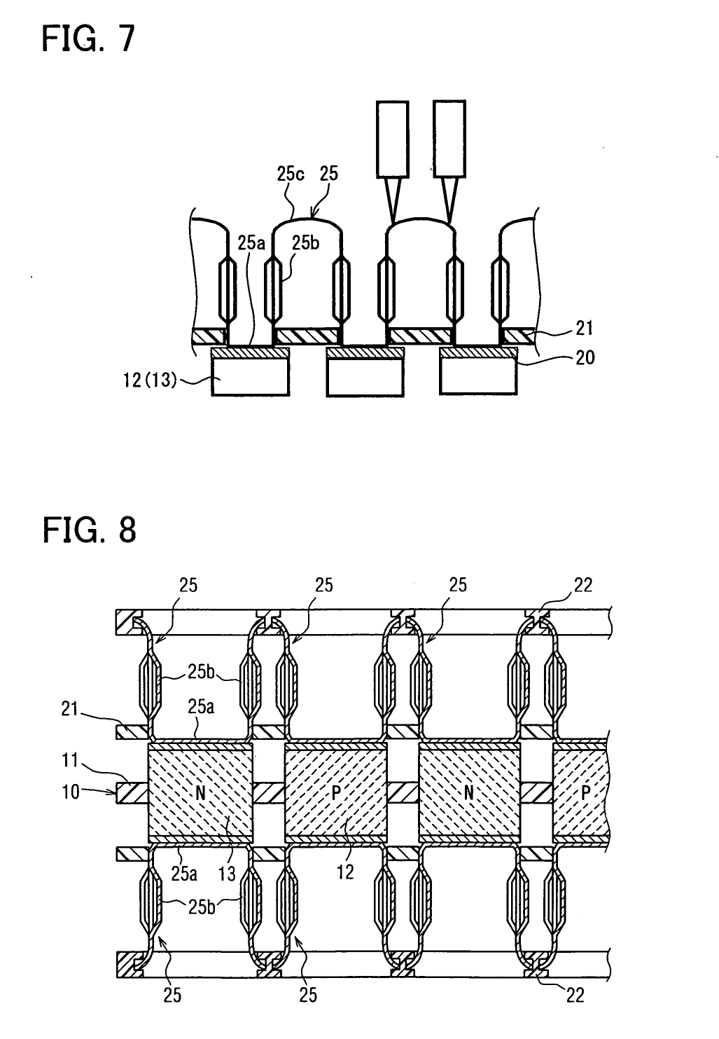

In this regard, when a laser process for applying laser light is used to cut the coupling portions 25c, as shown in FIG. 7, the reliability of process can be enhanced because cutting dust is not produced at the time of cutting and a cutting apparatus can be easily automated.

In this embodiment, the electrode portions 25a are put on the electrode members 20 in a state where the plurality of heat exchanging members 25 formed in the corrugated shape in the step of forming a heat exchanging member are provisionally mounted on the second insulating substrate 21 and then the electrode portions 25a are bonded by solder to the electrode members 20. However, it is not intended to limit the present invention to this embodiment, but it is also recommended that the plurality of heat exchanging members 25, formed in the corrugated shape in the step of forming a heat exchanging member, are not provisionally mounted on the second insulating substrate 21 but that the electrode portions 25a are directly put on the electrode members 20 and then are bonded by solder to them.

According to the manufacturing method by the steps described above, first, the plurality of heat exchanging members 25 are continuously formed by the step of forming a heat exchanging member and hence the number of forming steps required to form the heat exchanging members 25 can be decreased as compared with a conventional manufacturing method by which heat exchanging members are manufactured as single parts by press process.

Because the plurality of heat exchanging members 25 are formed continuously in the corrugated shape and are bonded to one end surfaces of the electrode members 20, the heat exchanging members 25 can be formed by rollers, which results in decreasing the number of steps required to form and mount the heat exchanging members 25 by a large amount. This can decrease the number of man-hours and steps necessary for manufacturing of the thermoelectric transducer.

The second insulating substrate 21 made of a plate-shaped insulating material is provided and the heat exchanging members 25 are bonded to the electrode members 20 in the state where the electrode portions 25a are provisionally mounted in the plurality of fitting holes formed at specified intervals in the second insulating substrate 21. Therefore, the heat exchanging members 25 can be easily mounted on the plurality of electrode members 20 arranged on the thermoelectric device substrate 10 and can be bonded at specified positions with reliability.

According to the manufacturing method of the thermoelectric transducer in accordance with the first embodiment described above, the plurality of electrode portions 25a and the plurality of louvers 25b are formed in succession continuously in the corrugated shape, then the electrode portions 25a are bonded to one end surfaces of the electrode members 20, and then the adjacent heat exchanging members 25 are electrically insulated from each other. Therefore, by forming a plurality of heat exchanging members 25 collectively and by mounting them on the electrode members 20, the number of steps required to form and mount the heat exchanging members 25 can be decreased by a large amount. This can decrease the number of forming steps and man-hours necessary for manufacturing.

When the manufacturing process is constructed in such a way that the heat exchanging members 25 are bonded to the electrode members 20 and that the coupling portions 25c are then cut, the heat exchanging members 25 can be easily connected in series to the thermoelectric devices 12, 13 via the electrode members 20. This can improve the ease of mounting the heat exchanging members 25. Moreover, by cutting the coupling portions 25c by laser, cutting dusts are not produced and the cutting step can be easily automated. This can improve the reliability of assembling.

The heat exchanging members 25 are provisionally assembled to the second insulating substrate 21, and then the heat exchanging members 25 are mounted to the electrode members 20. Therefore, the heat exchanging members 25 can be easily mounted to the plurality of electrode members 20 and can be bonded at the specified positions with reliability.

Specifically, the method for manufacturing a thermoelectric transducer has the step of forming a heat exchanging member and the step of bonding the heat exchanging member. Therefore, the number of steps required to form and mount the heat exchanging members 25 can be decreased by a large amount. This can decrease the number of forming steps and man-hours necessary for manufacturing.

The plurality of heat exchanging members 25 are formed continuously in the corrugated shape by roller process. In particular, as compared with press process, the roller process can improve productivity in the step of forming the louvers 25b by a large amount. Furthermore, as compared with the press process using female and male dies, the roller process can decrease manufacturing cost by a large amount.

### Second Embodiment

In the first embodiment described above, the heat exchanging members 25 are electrically insulated from each other by cutting the coupling portions 25c formed between the adjacent louvers 25c. However, this embodiment is constructed in such a way that the ends between the cut louvers 25 are fixed to a first fixing member 22.

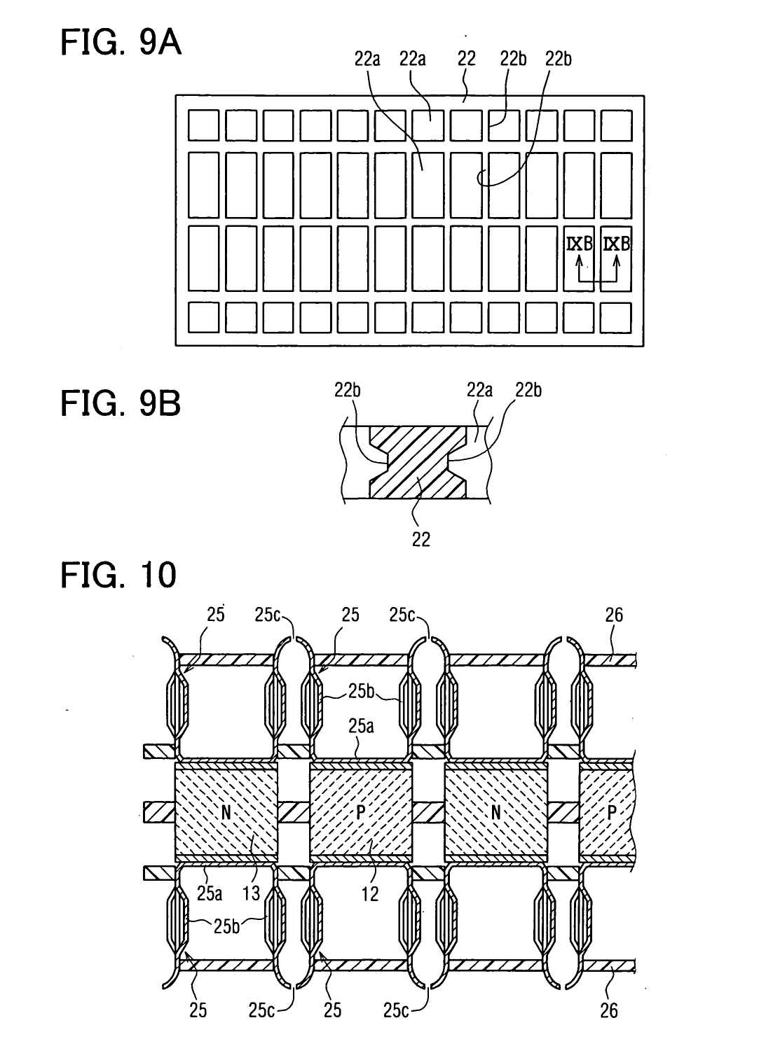

Specifically, as shown in FIG. 8 and FIGS. 9A and 9B, this second embodiment is constructed in such a way that the ends of the louvers 25 having the coupling portions 25c cut off are fixed by the first fixing member 22 shaped like a plate and made of an insulating material. That is, as shown in FIG. 9A and FIG. 9B, fixing holes 22a and depressed portions 22b are formed at specified intervals in the first fixing member 22 shaped like a plate and made of an insulating material, and the ends of the louvers 25 having the coupling portions 25c cut off are fixed by the first fixing member 22 after the cutting step of cutting the coupling portions 25c. This step is referred to as the step of mounting a fixing member.

When the coupling portions 25c are cut and left as they are as in the first embodiment and, for example, an external force is applied to the louvers 25b, there is a possibility that electric insulation can not be secured because a portion of the adjacent louvers 25 is deformed. However, according to this embodiment, the ends of the louvers 25b are fixed by the first fixing member 22 and hence electric insulation can be realized with reliability.

Moreover, in the second embodiment, as shown in FIG. 10, the coupling portions 25c can be fixed by a second fixing member 26 shaped like a plate and made of an insulating material, before cutting the coupling portions 25c. After the coupling portions 25c are fixed to the second fixing member 26, the coupling portions 25c are cut. According to this, in the cutting step, the second fixing member 26 can receive a cutting force and hence can prevent load from being applied to the bonding surface of the electrode portion 25a by cutting. Here, it is desirable to fix the second fixing member 22a to the heat exchanging members 25 by an adhesive or the like.

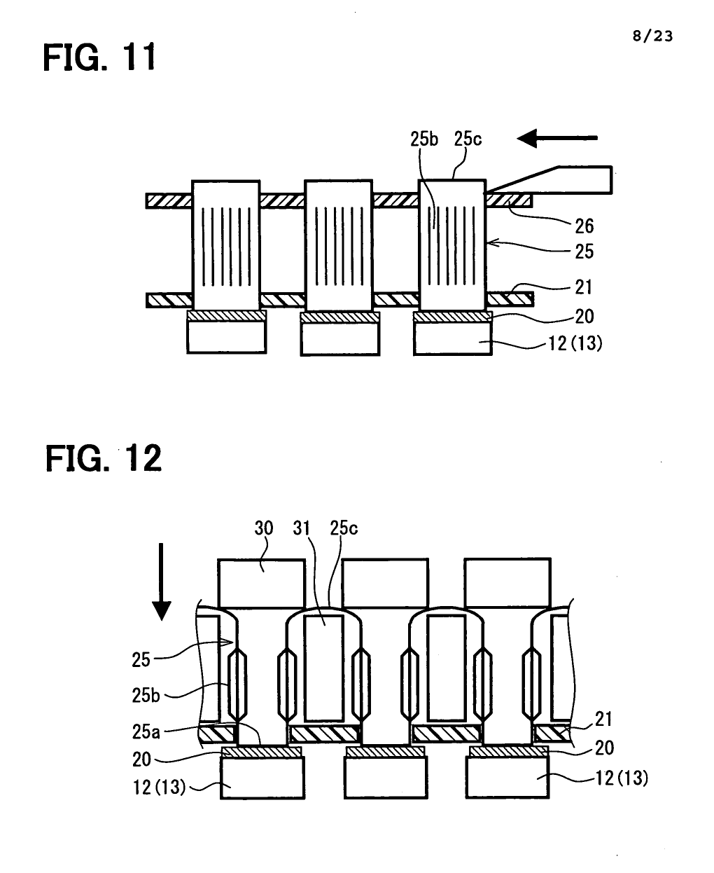

In the above-described first and second embodiments, the coupling portions 25c are cut by laser in the cutting step. However, the present invention is not limited to this but, as shown in FIG. 11, it is also recommendable to employ a construction that a cutter is slid in the direction shown by the arrow to cut the coupling portions 25c. Moreover, as shown in FIG. 12, it is also recommendable to employ a cutting process of punching the coupling portions 25c by putting a die 30 and a punch 31 on the coupling portions 25c. In addition to this, it is also recommendable to cut the coupling portions 25c by using a cutting jig. As a chemical method, it is also recommendable to employ a method for dissolving the coupling portions 25c by etching.

In the first and second embodiments described above, in the step of forming a heat exchanging member, the plurality of heat exchanging members 25 each having the louver 25b, the electrode portion 25a, the louver 25b and coupling portion 25c formed in succession continuously in the corrugated shape are formed by roller process by the use of rollers. However, it is not intended to limit the present invention to this embodiment, but the heat exchanging members 25 may be formed continuously using a press process in place of the roller process.

### Third Embodiment

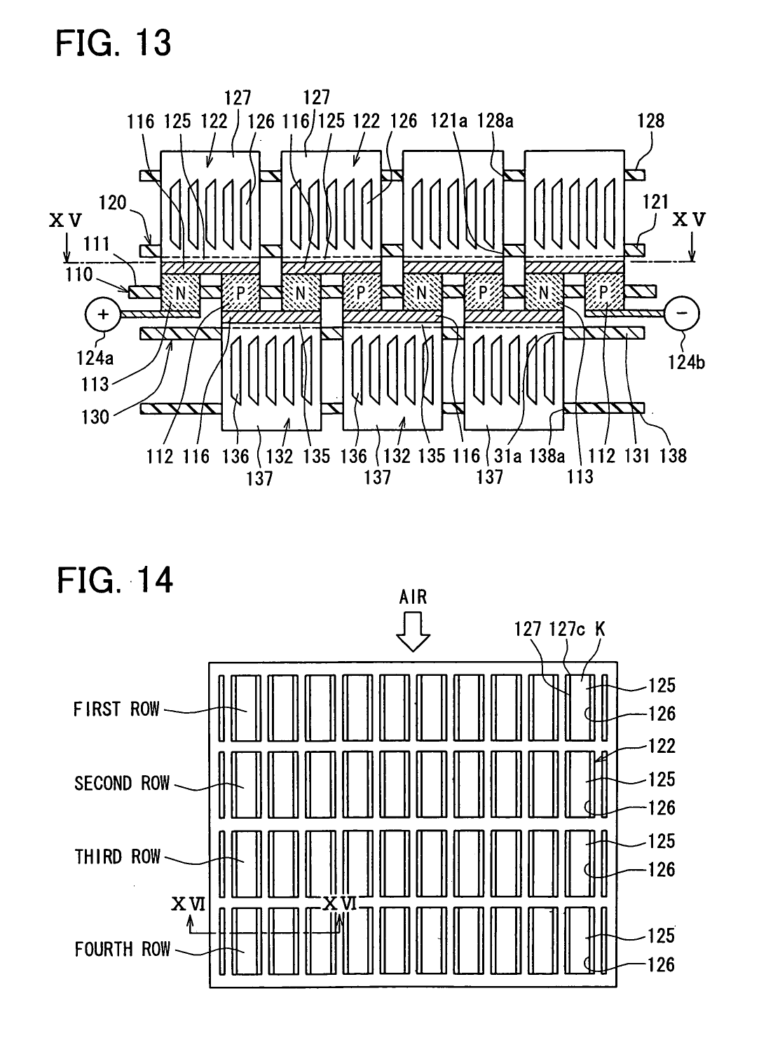

The third embodiment of the present invention will be now described with reference to FIGS. 13 to 22.

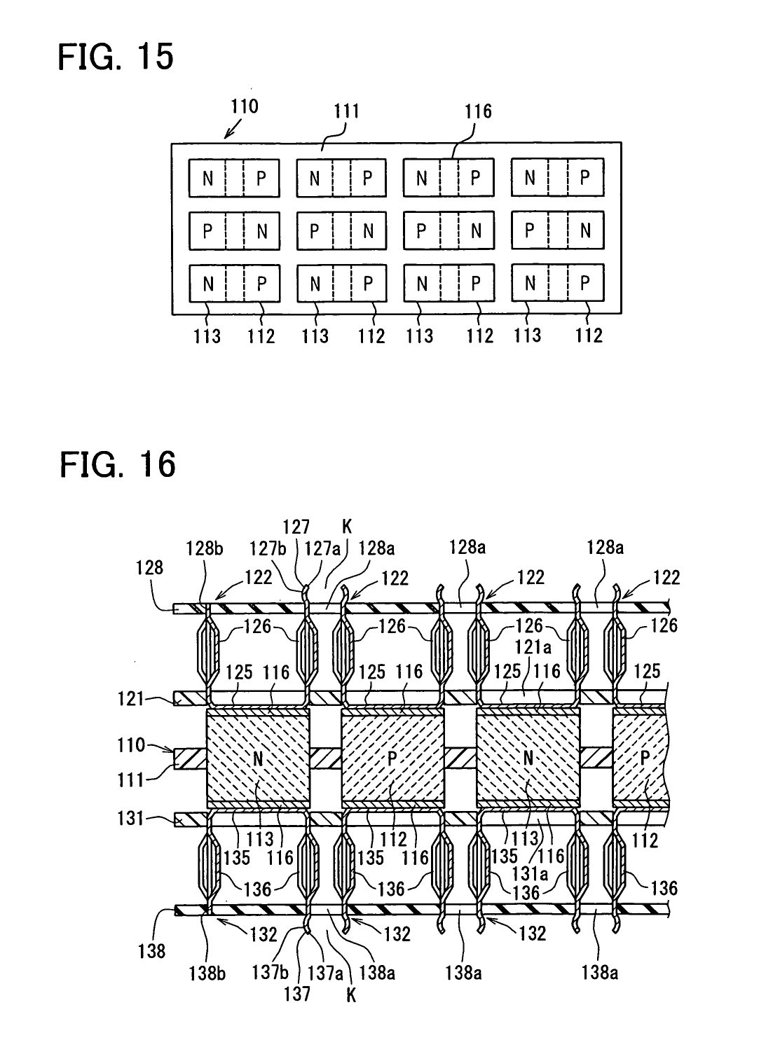

A thermoelectric transducer of this embodiment, as shown in FIG. 13, FIG. 15, and FIG. 16, is constructed of a thermoelectric device substrate 110 having a plurality of thermoelectric devices (to be more detailed, P-type thermoelectric devices 112 and N-type thermoelectric devices 113) set in a predetermined arrangement, electrode members 116 for electrically connecting the adjacent P-type thermoelectric devices 112 and N-type thermoelectric devices 113, heat exchanging members 122, 132 bonded to the electrode members 116 in such a way as to transmit heat, and first holding base members 128, 138 and second holding base members 121, 131 for holding the heat exchanging members 122, 132.

The thermoelectric device substrate 110, as shown in FIG. 15, has an insulating substrate 111 as a base member, and a group of thermoelectric devices which includes a plurality of P-type thermoelectric devices 112 and N-type thermoelectric devices 113. The P-type thermoelectric devices 112 and the N-type thermoelectric devices 113 are alternately arranged in rows on the insulating substrate 111, thereby they are integrated into one structure. Moreover, in this thermoelectric device substrate 110, the electrode members 116 are bonded to both end surfaces of the adjacent P-type thermoelectric devices 112 and N-type thermoelectric devices 113, thereby they are integrated into one structure.

The insulating substrate 111 is formed of an insulating material (for example, glass epoxy, PPS resin, LCP resin, or PET resin) in the shape of a plate.

The P-type thermoelectric device 112 is a well-known thermoelectric element constructed of a P-type semiconductor made of Bi—Te based compound, and the N-type thermoelectric device 113 is a well-known thermoelectric element constructed of an N-type semiconductor made of Bi—Te based compound. The P-type thermoelectric device 112 and the N-type thermoelectric device 113 used in this embodiment are extremely small components for a thermoelectric element and the thermoelectric device substrate 110 is integrally formed in such a way as to array the P-type thermoelectric devices 112 and the N-type thermoelectric devices 113 on the first insulating substrate 111 in a lattice pattern. At this time, the P-type thermoelectric devices 112 and the N-type thermoelectric devices 113 are set in such a way as to protrude their top end surfaces and bottom surfaces from the first insulating substrate 111.

The electrode member 116, as shown in FIG. 15, is an electrode shaped like a flat plate and formed of conductive metal such as copper. The electrode members 116 are arranged for electrically connecting the adjacent P-type thermoelectric devices 112 and N-type thermoelectric devices 113, among the group of thermoelectric devices arranged on the thermoelectric device substrate 110. In other words, a plurality of electrode members 116 are arranged on both ends of the adjacent thermoelectric devices 112, 113 in such a way that the thermoelectric devices 112, 113 are connected in series via the electrode members 116. Here, the electrode members 116 are bonded by solder to the end surfaces of the thermoelectric devices 112, 113.

Specifically, as shown in FIG. 13, both ends of the adjacent thermoelectric devices 112, 113 are connected electrically in series via the electrode members 116. Hence, an electric current passes from the N-type thermoelectric devices 113 to the P-type thermoelectric devices 112 on the upper end surfaces of the N-type thermoelectric devices 113 and the P-type thermoelectric devices 112, and an electric current passes from the P-type thermoelectric device 112 to the N-type thermoelectric devices 113 on the lower end surfaces of the N-type thermoelectric devices 113 and the P-type thermoelectric devices 112. A terminal 124a and a terminal 124b are provided respectively on the N-type thermoelectric device 113 (at the left end in the drawing) and the P-type thermoelectric device 112 (at the right end in the drawing) which are arranged on the left and right ends shown in the drawing. The positive terminal and the negative terminal of a DC power source (not shown) are connected to the terminals 124a and 124b, respectively.

In this manner, as to the electrode members 116 arranged on the upper side of the insulating member 111, a plurality of electrode members 116 are arranged on the end surfaces of the thermoelectric devices 112, 113 to electrically form NP junctions. As to the electrode members 116 arranged on the lower side of the insulating member 111, a plurality of electrode members 116 are arranged on the end surfaces of the thermoelectric devices 112, 113 to electrically form PN junctions. At this time, by Peltier effect, the lower electrode members 116 for forming the PN junctions and heat exchanging members (hereinafter referred to as “heat exchanging member for radiating heat”) 132 are brought into the state of high temperature, and the upper electrode members 116 for forming the NP junctions and heat exchanging members (hereinafter referred to as “heat exchanging member for absorbing heat”) 122 are brought into the state of low temperature.

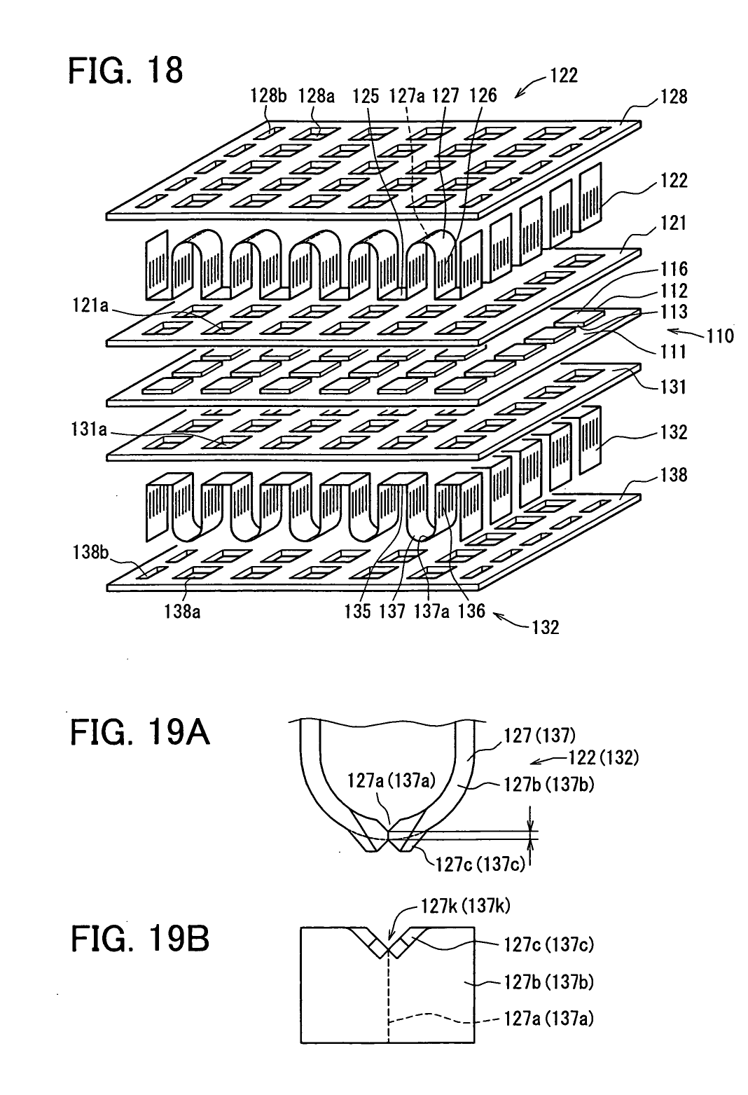

Each of the heat exchanging members 122 (132) (to be more detailed, heat exchanging member 122 for absorbing heat and heat exchanging member 132 for radiating heat) is constructed with an electrode portion 125 (135), heat exchanging portions 126 (136), and a coupling portion 127 (137). The adjacent heat exchanging members 122 (132), as shown in FIG. 18, are formed in such a way to be connected to each other via the coupling portion 127 (137) for connecting the adjacent heat exchanging portions 126 (136). Then, the adjacent heat exchanging members 122 (132) are electrically insulated from each other, respectively.

Specifically, a plurality of continuously connected heat exchanging members 122 (132) are formed continuously in a corrugated shape, that is, in the shape of a so-called corrugated fin by the use of a plate made of conductive metal such as copper and having a specified thickness (about 0.3 mm in this embodiment), as shown in FIG. 18. Further, each of the heat exchanging members 122 (132) includes an electrode portion 125 (135), heat exchanging portions 126 (136) connected to two ends of the electrode portion 125 (135), and a coupling portion 127 (137) for coupling the adjacent heat exchanging portions 126 (136). Then, the adjacent heat exchanging members 122 (132) are electrically insulated from each other by cutting off the arm portions 127b (137b not shown, ditto for the following) of the coupling portions 127 (137) (refer to FIG. 16).

Each of the electrode portions 125 (135), as shown in FIG. 13 and FIG. 16, is nearly in the shape of a flat portion and is bonded to each of the electrode members 116 in such a way as to transmit heat. The electrode portion 125 (135) is connected by solder to the end surface of the electrode member 116.

The heat exchanging portion 126 (136) has a louver and the louver is formed between the coupling portion 127 (137) on the crest side and the electrode portion 125 (135) on the trough side, which are continuously formed in a corrugated shape, in such a way as to be cut and raised between the crest and the trough in the corrugated shape. In this embodiment, the louver is fins for absorbing or radiating heat transmitted from the electrode portion 125 (135).

The coupling portion 127 (137), as shown in FIG. 13 and FIG. 16, has the arm portion 127b (137b) formed nearly in the shape of an arc and to be divided. The arm portion 127b (137b) corresponds to an arch portion (curved portion).

The corner of the divided arm portion 127b has a cut-raised portion 127c which will be described later. The cut-raised portion 127c does not have to remain at the corner of the divided arm portion 127b. For example, the coupling portion 127 (137) can be cut off by a small cutting force by the use of a cutting blade 170 without producing cuttings. As a result, it is possible to provide a thermoelectric transducer capable of realizing excellent productivity.

At the portion of the coupling portion 127 (137), as shown in FIG. 19A and FIG. 19B, a notch groove 127a (137a) is previously formed along the direction in which cutting is to be performed on the inside of bending to which the arm portion 127b (137b) of the coupling portion 127 (137) is bent. Here, the notch groove 127a (137a) and the cut-raised portion 127c (137c) are provided such that the cut-raised portion 127c (137c) is formed by cutting and raising the coupling portion 127 (137) from a starting point at the end portion of the notch groove 127a (137a).

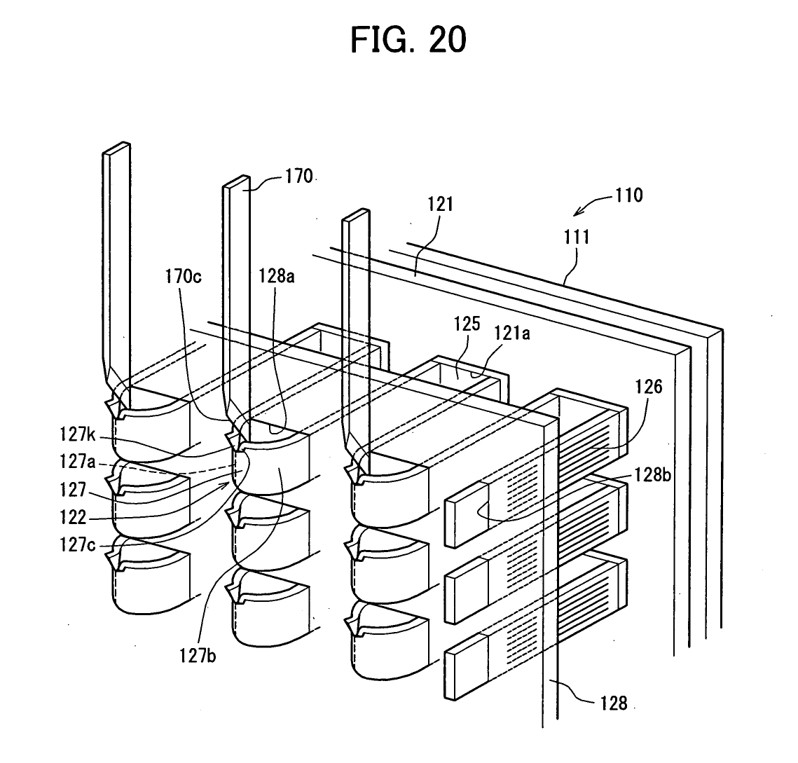

This cut-raised portion 127c (137c), as shown in FIG. 20, is cut and raised in such a way as to follow the shape of the cutting edge of the cutting blade 170. With this, the cutting edge of the cutting blade 170 is guided smoothly along a V-shaped notch 127k (137k) for guiding the cutting blade 170 formed by the cut-raised portions 127c (137c).

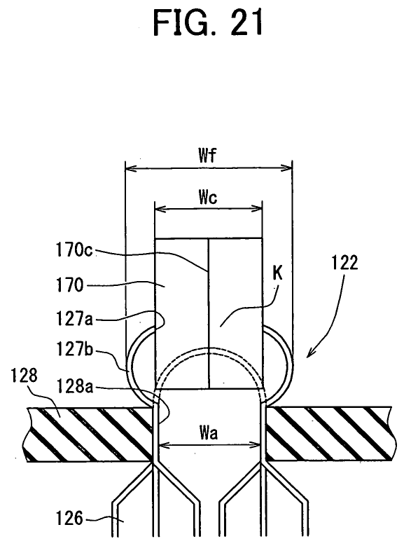

The width Wf (refer to FIG. 21) of the divided arm portion 127b (137b) is made larger than the width Wa of the heat exchanging portion 126 (136) (to be more detailed, the width of a portion fitted in a first fitting hole 128a (138a)). Accordingly, a cut-off portion K for securing insulation is surely formed between the divided arm portions 127b (137b) (refer to FIG. 14 and FIG. 16). By cutting and raising the arm portion 127b (137b) divided in this manner to the blade width Wc of the cutting blade 70, the insulation after cutting of the coupling portion 127 (137) can be enhanced.

The first holding base member 128 (138) is constructed of a plate-shaped insulating substrate made of an insulating material (for example, glass epoxy, PPS resin, LCP resin, or PET resin). Fitting holes 128a (138a) in which the coupling portions 127 (137) can be fitted are formed in the first holding base member 128 (138). The coupling portion 127 (137) is fitted in the fitting hole 128a (138a) to integrate the heat exchanging member 122 (132) with the first holding base member 128 (138).

The second holding base member 121 (131) is constructed of a plate-shaped insulating substrate made of an insulating material (for example, glass epoxy, PPS resin, LCP resin, or PET resin). Fitting holes 121a (131a) in which the electrode portions 125 (135) can be fitted are formed in the second holding base member 121 (131). The electrode portion 125 (135) is fitted into the fitting hole 121a (131a) to integrate the heating exchanging member 122 (132) with the second holding base member 121 (131).

Here, the coupling portion 127 of the heat exchanging member 122 for absorbing heat and the electrode portion 125 for absorbing heat are fitted in the first fitting hole 128a and the second fitting hole 121a so as to construct a heat-absorbing electrode substrate 120 for integrally holding the heat exchanging portion 122 by using the first holding base member 128 and the second holding base member 121. The heat-absorbing electrode substrate 120 constructs a corrugated heat exchanging member assembly. The heat-absorbing electrode portion 125 and the heat exchanging portion 126 construct a heat absorbing portion. Here, the heat exchanging portion 122 for absorbing heat is a heat exchanging portion for absorbing heat.

The coupling portion 137 of the heat exchanging member 132 for radiating heat and the heat-radiating electrode portion 135 are fitted in the first fitting hole 138a and the second fitting hole 131a so as to construct a heat-radiating electrode substrate 130 for integrally holding the heat exchanging member 132 by using the first holding base member 138 and the second holding base member 131. The heat-radiating electrode substrate 130 constructs a corrugated heat exchanging member assembly. Here, the heat-radiating electrode portion 135 and the heat exchanging portion 136 construct a heat radiating portion.

A thermoelectric transducer having the above-described construction, as shown in FIG. 13, forms an air passage by a case member (not shown) on two sides of the thermoelectric device substrate 110 by using the thermoelectric device substrate 110 as a partitioning wall. Air passes through the air passage (refer to FIG. 14), thereby the louvers of the heat exchanging portions 126 (136) exchange heat with air. Because the louvers of the heat exchanging portions 126 exchange heat with air, the heat exchanging member 122 for absorbing heat arranged on the upper side of the thermoelectric device substrate 110 cools air by the heat exchanging portions 126. Meanwhile, because the louvers of the heat exchanging portions 136 exchange heat with air, the heat exchanging member 132 for radiating heat arranged on the lower side of the thermoelectric device substrate 110 heats air by the heat exchanging portions 136.

The heat exchanging members 122 (132) of the thermoelectric transducer of the third embodiment are constructed in the following manner: a plurality of electrode portions 125 (135) electrically bonded to the electrode members 116 in such a way as to transmit heat, a plurality of heat exchanging portions 126 (136) connected to both the ends of the electrode portions 125 (135), and a plurality of coupling portions 127 (137) for coupling the adjacent heat exchanging portions 126 (136) are formed continuously in the corrugated shape; and then the coupling portions 127 (137) are divided in such a way as to make the corners of the arm portions 127b (137b) of the divided coupling portions 127 (137) have the cut-raised portions 127c (137c).

The coupling potion 127 (137) can be cut off by a small cutting force without producing cutting dusts. As a result, it is possible to provide a thermoelectric transducer capable of realizing excellent productivity.

The thermoelectric transducer of the third embodiment is provided with the first holding base members 128, 138 having the first fitting holes 128a, 138a through which the coupling portions 127, 137 can be passed and the second holding base members 121, 131 having the second fitting holes 121a, 131a through which the electrode portions 125, 135 can be passed. The coupling portions 127, 137 are passed through the first fitting holes 128a, 138a and the electrode portions 127, 137 are passed through the second fitting holes 121a, 131a so as to form the corrugated heat exchanging member assemblies 120, 130.

Accordingly, even if the corrugated heat exchanging member assemblies 120, 130 are formed before or after the electrode portions 125, 135 are bonded to the thermoelectric devices 112, 113 via the electrode members 116, when the coupling portions 127, 137 are cut off in order to secure insulation between the adjacent heat exchanging members 122, 132, it is possible to lessen or prevent an effect on the thermoelectric devices 112, 113, which are comparatively brittle, by cutting process.

Moreover, the thermoelectric transducer of this embodiment is constructed in such a way that the divided arch portions 127b, 137b are so cut and raised as to make width Wf of the arm portions 127, 137 larger than the width Wa of the heat exchanging portions 126, 137.

In this manner, by cutting and raising the divided arm portions 127b, 137b, the insulation after cutting of the coupling portions 127, 137 can be improved.

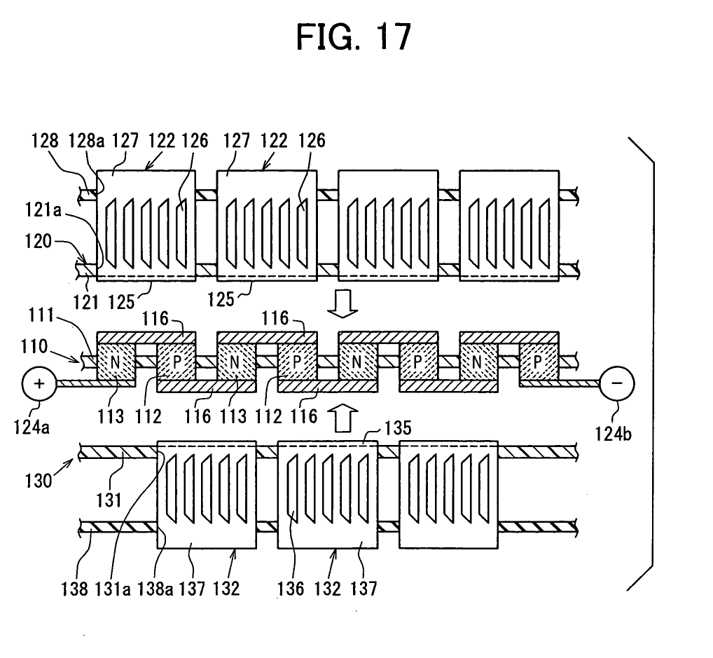

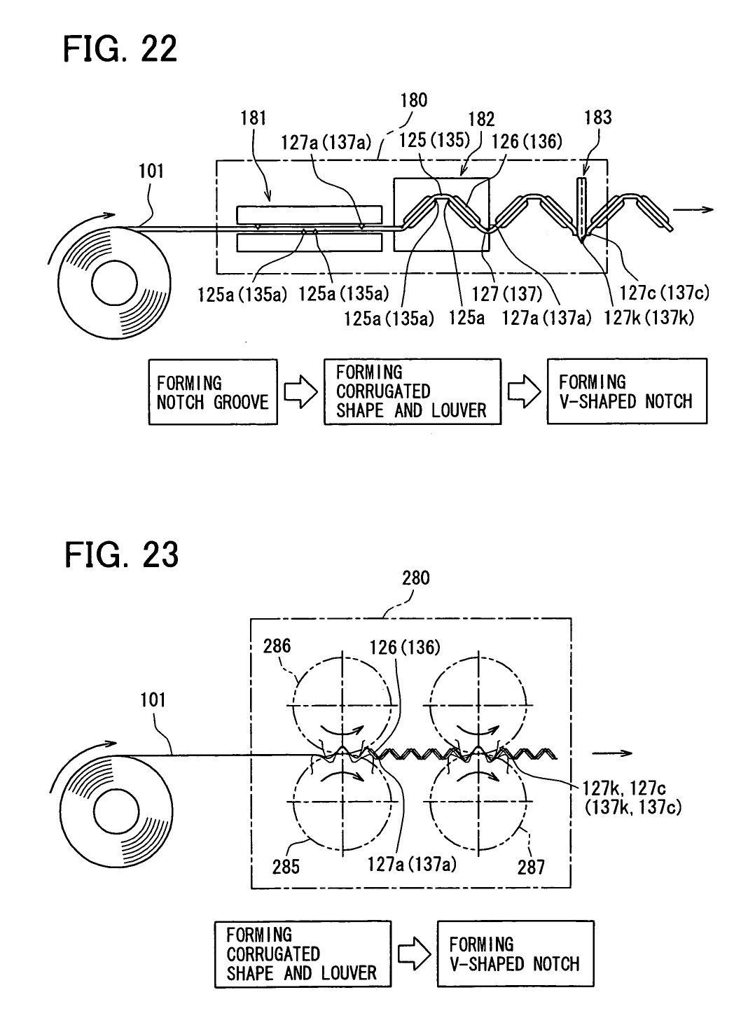

Next, a method for manufacturing a thermoelectric transducer and a method for forming a corrugated fin will be described. Through the method, a plurality of heat exchanging members 122, 132 used for a thermoelectric transducer are formed continuously in a corrugated shape. FIGS. 17 to 21 are diagrams illustrating the process of the method for manufacturing the thermoelectric transducer. FIG. 22 is a diagram illustrating the process of a method for forming a corrugated fin.

The method for manufacturing a thermoelectric transducer includes the step of assembling a thermoelectric device, the step of bonding an electrode member, the step of forming a heat exchanging member, the step of forming a corrugated heat exchanging member assembly, the step of bonding the heat exchanging member, and the step of cutting.

In the step of assembling a thermoelectric device, as shown in FIG. 15, a plurality of P-type thermoelectric devices 112 and a plurality of N-type thermoelectric devices 113 are arranged alternately in a lattice pattern in the holes formed in the insulating substrate 111, to form the thermoelectric device substrate 110 having the thermoelectric devices 112, 113 integrally mounted on the insulating substrate 111. At this time, it is also recommendable to manufacture the thermoelectric device substrate 110 by using a mounting apparatus for mounting a semiconductor, an electronic component, and the like.

In the step of bonding electrode members, as shown in FIG. 15, the electrode members 116 each formed in the shape of a flat plate are picked up and put on the end surfaces of the thermoelectric devices 112, 113 arranged in a specified arrangement on the insulating substrate 111, thereby a plurality of sets of electrode members 116 and thermoelectric devices 112, 113 are arranged, and then the thermoelectric devices 112, 113 and the electrode members 116 are bonded to each other by soldering.

This step of bonding an electrode member is carried out for each surface of both surfaces of the thermoelectric device substrate 110, for example, first, for the obverse surface and then for the reverse surface. That is, the electrode members 116 are bonded to one surfaces of the thermoelectric devices 112, 113, and then the thermoelectric device substrate 110 is turned upside down and the other electrode members 116 are bonded to the other surfaces of the thermoelectric devices 112, 113. Moreover, when paste solder is previously applied by screen printing to the bonding surfaces of the end surfaces of the thermoelectric devices 112, 113 and then the step of bonding the electrode members 116 to the bonding surfaces of the thermoelectric devices 112, 113 is performed, the bonding step by soldering can be easily carried out.

In the step of forming a heat exchanging member, as shown in FIG. 18, a plurality of heat exchanging members 122 for absorbing heat and a plurality of heat exchanging members 132 for radiating heat are continuously formed in the corrugated shape. In the following description of this embodiment, for the sake of simplifying description, a method for forming the heat exchanging member 122 for absorbing heat is described and the description of a method for forming the heat exchanging member 132 for radiating heat will be omitted.

In the step of forming a heat exchanging member, as shown in FIG. 18 and FIG. 22, a plurality of heat exchanging members (heat exchanging members for absorbing heat) 122, each of which includes the heat exchanging portion 126, the electrode portion (heat absorbing electrode portion) 125, the heat exchanging portion 126, and the coupling portion 127 in this order, are formed continuously in a corrugated shape by the use of a belt-shaped conductive material (hereinafter referred to as “fin material”).

Furthermore, as shown in FIG. 19A and FIG. 22, this step of forming a heat exchanging member includes the step of forming a notch groove by which a notch groove 127a (137a) is formed in the above-described coupling portion 127 (137) in the direction in which the coupling portion 127 (137) is to be cut, and the step of forming a cut-raised portion by which the coupling portion 127 (137) is cut and raised from a starting point at the end of the notch groove 127a (137a) to thereby form the cut-raised portion 127c (137c).

Specifically, in the step of forming a notch groove, as shown in FIG. 19A and FIG. 19B, the notch groove 127a is formed in the coupling portion 127 in the direction in which the coupling portion 127 is to be cut off by the cutting blade 170. Moreover, in the step of forming a cut-raised portion, the arm portion 127b of the coupling portion 127 (137) is cut and raised from a starting point at the ends of the notch groove 127a (137a). Accordingly, in this step of forming a cut-raised portion, the cut-raised portion 127c is cut and raised at the corners of the arm portion 127b of the coupling portion 127 to form a V-shaped notch 127k for guiding the cutting blade 170.

As a method for forming a plurality of heat exchanging members 122 (132) continuously in the corrugated shape, as shown in FIG. 22, a forming method using press process can be employed. The forming method using press process will be described later in detail.

In the step of forming a corrugated heat exchanging member assembly, as shown in FIG. 17, the coupling portions 127 (137) and the electrode portions 125 (135) of the plurality of heat exchanging members 122 (132) formed continuously in the corrugated shape are fitted in the first fitting holes 128a (138a) of the first holding base member 128 (138) and the second fitting holes 121a, 131a of the second holding base member 121 (131), to thereby form the corrugated heat exchanging member assembly 120 (130) in which the heat exchanging members 122 (132) are integrally mounted on the first holding base member 128 (138) and the second holding base member 121 (131).

The step of forming a corrugated heat exchanging member assembly has the step of forming the first holding base member 128 (138) and the step of forming the second holding base member 121 (131) as its preceding steps. In the step of forming the first holding base member 128 (138), the first fitting holes 128a (138a) through which the coupling portions 127 (137) can be passed are formed in the first holding base member 128 (138) for holding the coupling portions 127 (137). In the step of forming the second holding base member, the second fitting holes 121a (131a) in which the electrode portions 125 (135) can be fitted are formed in the second holding base member 121 (131) for holding the electrode portions 125 (135).

In the step of bonding a heat exchanging member, as shown in FIG. 17, the electrode portions 125 (135) of the corrugated heat exchanging member assembly 120 (130) are bonded by soldering to one end surfaces of the electrode portions 116 bonded in the step of bonding an electrode member. Here, specifically, a plurality of portions to be bonded of the heat-absorbing electrode portions 125 of the corrugated heat exchanging member assembly 120 and the one end surfaces of the electrode members 116 are bonded in unison. Moreover, a plurality of portions to be bonded of the heat-radiating electrode portions 135 of the corrugated heat exchanging member assembly 130 and the one end surfaces of the electrode members 116 are bonded at one time.

In the step of cutting, as shown in FIG. 20, the cutting blades 170 of cutters or the like are moved relatively toward the cut-raised portions 127c (137c) of the coupling portions 127 (137) to cut the coupling portions 127 (137). Specifically, as shown in FIG. 20 and FIG. 21, in this step of cutting, the cutting blades 170 are moved relatively toward the arm portions 127b protruding from the fitting holes 128a of the corrugated heat exchanging member assembly 120 to divide the arm portions 127c of the coupling portions 127 along the direction in which cutting is to be carried out.

At this time, as shown in FIG. 21, the cutting blade 170 is moved relatively toward the arch portion 127b. As a result, the arch portion 127c is cut and raised in the direction of width of the fitting hole 128a by the thickness Wc of the cutting blade 170.

In the manufacturing method of this embodiment described above, the notch grooves 127a (137a) are formed in the coupling portions 127 (137) in the direction in which the coupling portions 127 (137) are to be cut, and the coupling portions 127 (137) are cut and raised from the starting points at the ends of the notch grooves 127a (137a) and then the cutting blades 170 are moved relatively toward the cut-raised portions 127c (137c) of the coupling portions 127 (137).

According to this, the coupling portions 127 (137) are cut and raised from the starting points at the ends of the notch grooves 127a (137a). Hence, the cut-raised portions 127c (137c) capable of guiding the cutting blades 170 can be formed in the notch grooves 127a (137a). As a result, when the coupling portions 127 (137) are cut off by the cutting blades 170, the cutting blades 170 can be accurately guided to the notch grooves 127a (137a) along the cut-raised portions 127c (137c).

The notch grooves 127a (137a) each having a thin part in the coupling portions 127 (137) can be cut off by the cutting blades 170. Therefore, the coupling portions 127 (137) can be cut off by a small cutting force without producing cutting dusts.

Moreover, in the manufacturing method of this embodiment, the first fitting holes 128a (138a) through which the coupling portions 127 (137) can be passed are formed in the first holding base member 128 (138) for holding the coupling portions 127 (137), and then the coupling portions 127 (137) are passed through the first fitting holes 128a (138a) to be held. Therefore, the cutting blades 170 are moved relatively toward the arm portions 127b (137b) of the coupling portions 127 (137) protruding from the first fitting holes 128a (138a) to cut and raise the arm portions 127b (137b) in the direction of width of the fitting holes 128a (138a).

According to this, when the cutting blades 170 are moved relatively toward the arm portions 127b (137b), that is, the V-shaped notches 127k (137k) of the coupling portions 127 (137) protruding from the first fitting holes 128a (138a) to cut off the coupling portions 127 (137) along the notch grooves 127a (137a), the arm portions 127b (137b) can be divided by the thickness of the cutting blade 70 and can be raised. In this manner, by cutting and raising the divided arm portions 127b (137b), it is possible to improve insulation after the cutting of the coupling portions 127 (137).

Furthermore, in this embodiment, the manufacturing method of this embodiment includes the step of forming the second fitting holes 121a (131a), in which the electrode portions 125 (135) can be inserted, in the second holding base member 121 (131) for holding the electrode portions 125 (135), the step of fitting the electrode portions 125 (135) into the second fitting holes 121a (131a), and the step of moving the cutting blades 170 relatively toward the cut-raised portions 127c (137c) of the coupling portions 127 (137).

According to this method, the electrode portions 125 (135) are fitted in the second fitting holes 121a (131a) and then the coupling portions 127 (137) are cut off by the cutting blades 170. Hence, even if the reactive forces of the cutting forces by the cutting blades 170 are applied to the coupling portions 127 (137), the acting forces can be diffused to the second holding base member 121 (131) in which the electrode portions 125 (135) connected via the heat exchanging portions 126 (136) to the coupling portions 127 (137) are fitted.

Therefore, it is possible to cut off the coupling portions 127 (137) by a small cutting force without producing cutting dusts and to lessen an effect on the thermoelectric devices 112, 113, which are comparatively brittle, at the time of cutting process.

In the manufacturing method of this embodiment, the corrugated heat exchanging member assembly 120 (130) is formed by inserting the coupling portions 127 (137) into the first fitting holes 128a (138a) and fitting the electrode portions 125 (135) in the second fitting holes 121a (131a). Furthermore, the corrugated heat exchanging member assembly 120 (130) are formed and then the cutting blades 170 are moved relatively toward the arm portions 127b (137b) of the coupling portions 127 (137).

Accordingly, the coupling portions 127 (137) can be cut off before the electrode portions 125 (135) are bonded to the thermoelectric devices 112 (113) via the electrode members 116, that is, at the state in which the corrugated heat exchanging member assembly 120 (130) is formed. As a result, at the time of cutting, the cutting force does not have an effect on the thermoelectric devices, which are comparatively brittle, at the time of cutting process.

The manufacturing method of this embodiment includes the steps of: forming a heat exchanging member; forming a notch groove; and forming a cut-raised portion. In the step of forming the heat exchanging member, a plurality of heat exchanging members 122 (132), each of which includes the heat exchanging portion 126 (136), the electrode portion 125 (135), the heat exchanging portion 126 (136), and the coupling portion 127 (137) in this order, are formed continuously in the corrugated shape by the use of a belt-shaped conductive fin material 101. In the step of forming the notch groove, the notch grooves 127a (137a) are formed on the coupling portions 127 (137) in the direction in which the coupling portions 127 (137) are to be cut. Furthermore, in the step of forming the cut-raised portion, the coupling portions 127 (137) are cut and raised from the starting points at the ends of the notch grooves 127a (137a) to thereby form the cut-raised portions 127c (137c).

In this manner, by forming the plurality of heat exchanging members 122, 132 continuously in the corrugated shape and by bonding them to one end surfaces of the electrode members 116, it is possible to decrease the number of steps required to form and to mount the heat exchanging members 122, 132 by a large amount. As a result, it is possible to realize excellent productivity.

Moreover, the manufacturing method of this embodiment includes the steps of: forming the first holding base member in which the first fitting holes 128a (138a), into which the coupling portions 127 (137) can be inserted, are formed in the first holding base member 128 (138) for holding the coupling portions 127 (137); forming the second holding base member in which the second fitting holes 121a (131a), into which the coupling portions 127 (137) can be inserted, are formed in the second holding base member 121 (131) for holding the electrode portions 125 (135); and forming a corrugated heat exchanging member assembly in which the coupling portions 127 (137) are fitted in the first fitting holes 128a (138a) and the electrode portions 125 (135) are fitted in the second fitting holes 128a (138a) to form the corrugated heat exchanging member assembly 120 (130).

With this, even if the corrugated heat exchanging member assembly 120 (130) is formed before or after the electrode portions 125 (135) are bonded to the thermoelectric devices 112 (113) via the electrode members 116, at the time of cutting the coupling portions 127 (137) in order to secure insulation between the adjacent heat exchanging member 122 (132), the reactive force to the coupling portions 127 (137) by the cutting force can be absorbed by the corrugated heat exchanging member assembly 120 (130). As a result, it is possible to restrict or prevent an effect on the thermoelectric devices, which are comparatively brittle, by the cutting force.

Furthermore, the manufacturing method of this embodiment includes: the step of cutting in which the cutting blades 170 are moved toward the cut-raised portions 127c (137c) of the coupling portions 127 (137).

When the coupling portions 127 (137) are cut to secure insulation between the adjacent heat exchanging members 122 (132), there is provided the step of cutting in which the cutting blades 170 are moved toward the cut-raised portions 127c (137c) of the coupling portions 127 (137). As a result, it is possible to divide the coupling portions 127 (137) by a small cutting force without producing cutting dust.

Furthermore, in the manufacturing method of this embodiment, the step of cutting is constructed in such a way as to cut and raise the arm portions 127b (137b) of the coupling portions 127 (137) by moving the cutting blades 170 relatively.

With this, by cutting and raising the divided arm portions 127b (137b), it is possible to improve insulation after the cutting of the coupling portions 127 (137).

Next, a method for forming a corrugated fin will be described with reference to FIG. 22. As shown in FIG. 22, a plurality of continuously connected heat exchanging members 122 (132), each of which includes the heat exchanging portion 126 (136), the electrode portion 125 (135), the heat exchanging portion 126 (136), and the coupling portion 127 (137) in this order, are formed continuously in the corrugated shape by pressing a belt-shaped fin material 101.

As shown in FIG. 22, the method for forming a corrugated fin includes the steps of: forming a notch groove in which a notch groove 127a (137a) is formed in the coupling portion 127 (137) in the direction in which the coupling portion 127 (137) is to be cut; forming a corrugated shape in which the belt-shaped fin material 101 is bent at the portions between the electrode portion 125 (135), the heat exchanging portion 126 (136), and the coupling portion 127 (137) to form a crest and a trough, thereby being brought into a corrugated shape; forming a louver by which a louver is cut and raised in the heat exchanging portion 126 (136), between the crest and the trough in the corrugated shape; and cutting and raising a cut-raised portion 127c (137c) for guiding the cutting blade 170 from a starting point at the end of the notch groove 127a (137a).

In this manner, this method can realize excellent productivity as a method for forming a corrugated fin used for the thermoelectric transducer in which P-type thermoelectric devices 112 and N-type thermoelectric devices 113 are arranged alternately on the insulating substrate 111 and in which heat exchanging members 122, 132 bonded to electrode members 116 bonded to the adjacent P-type thermoelectric devices 112 and N-type thermoelectric devices 113 are electrically insulated from each other.

In this embodiment, in the step of forming a notch groove, it is preferable to form the notch groove 125a (135a) inside the bent portion between the electrode portion 125 (135) of a flat portion and the heat exchanging portion 126 (136). Even when the heat exchanging member 122 (132) are formed of a fin material of a relatively large thickness (e.g., about 0.3 mm, in this embodiment), the plurality of heat exchanging members 122 (132) can be formed easily continuously in the corrugated shape. As a result, this method can realize excellent productivity as the method for forming a relatively thick corrugated fin.

Reference numeral 181 in FIG. 22 denotes a pushing-out press machine (pressing press machine) for forming a notch groove 127a on the belt-shaped fin material 101, reference numeral 182 denotes a compound press machine for performing corrugating process in which the belt-shaped fin material 101 is formed into the corrugated shape and for performing louver process in which the louvers of the heat exchanging portion 126 (136) are cut and raised, and reference numeral 183 denotes a cutting and raising press machine for cutting and raising the coupling portion 127 (137) from the starting point at the end of the notch groove 127a (137a). Here, the pressing press machine 181, the compound press machine 182, and the cutting and raising press machine 183 construct a manufacturing apparatus for forming a plurality of heat exchanging members 122, 132 continuously into the corrugated shape by press process.

Although a forming method using press process has been described as a manufacturing method for forming a plurality of heat exchanging members 122, 132 continuously in the corrugated shape in the third embodiment described above, a forming method using roller process as shown in FIG. 23 may be employed. In FIG. 23, reference numeral 286 denotes a corrugating roller, reference numeral 285 denotes a knurling roller for cutting and raising a louver and forming a notch groove, reference numeral 287 denotes V-shaped notch forming rollers for cutting and raising the cut-raised portion 127a (137a) in order to form a V-shaped notch 127k (137k). Here, the corrugating roller 286, the knurling roller 285, and the V-shaped notch forming rollers 287 construct a manufacturing apparatus for forming a plurality of heat exchanging members 122, 132 continuously by roller process.

In the step of corrugating and the step of forming a louver, the belt-shaped fin material 101 is corrugated by the use of the corrugating roller 286 and the knurling roller 285, and the louver of the heat exchanging portion 126 (136) is cut and raised. Then, the notch groove 127a (137a) is formed in the coupling portion 127 (137) in the direction in which the coupling portion 127 (137) is to be cut. After the step of corrugating and the step of forming a louver are finished, in the step of forming a cut-raised portion, the cut-raised portion 127c (137c) is cut and raised by the V-shaped notch forming rollers 287 in such a way as to form the V-shaped notch 127k (137k) at the end of the notch groove 127a (137a) of the coupling portion 127 (137).

Also by this construction, the same effect as in the third embodiment can be obtained. Moreover, by subjecting the belt-shaped fin material 101 to roller process, a plurality of heat exchanging members 122 (132) can be formed continuously in the corrugated shape, that is, in the shape of a so-called corrugated fin. As a result, it is possible to realize excellent productivity.

The third embodiment described above uses the manufacturing process including the step of forming the corrugated heat exchanging member assembly 120 (130), the step of bonding the electrode portions 125 (135) of the corrugated heat exchanging member assembly 120 (130) to the electrode members 116 of the thermoelectric device substrate 110, and the step of cutting the arm portions 127b (137b) of the coupling portions 127 (137). However, it is also recommendable to use the manufacturing process including the step of forming the corrugated heat exchanging member assembly 120 (130) and the step of cutting the arm portions 127b (137b) of the coupling portions 127 (137).

With this, even in any of the manufacturing process, it is possible to restrict or prevent an affect on the thermoelectric devices, which are relatively brittle, due to the cutting force at the time cutting the coupling portions 127 (137). In a case where the coupling portions 127 (137) are cut after the corrugated heat exchanging member assembly 120 (130) is formed, it is possible to prevent an affect on the thermoelectric devices, which are relatively brittle, due to the cutting force.

In the above described third embodiment, the notch groove 127a (137a) formed at a position to be cut of the coupling portion 127 (137) is formed inside a bent portion, in which the arm portion 127b (137b) of the coupling portion 127 (137) is bent, along the direction in which the coupling portion 127 (137) is to be cut. However, the notch groove 127a (137a) does not necessarily have to be formed inside a bent portion where the coupling portion 127 (137) is bent, but the notch groove 127a (137a) may be formed outside a bent portion where the coupling portion 127 (137) is bent.

In the above-described third embodiment, the V-shaped notch 127k (137k) for guiding the cutting blade 170 is formed at the end of the notch groove 127a (137a) on the side where the cutting blade 170 is moved relatively toward the coupling portion 127 (137). However, the V-shaped notch 127k (137k) does not necessarily have to be formed at one end of the notch groove 127a (137a) in the direction in which the notch groove 127a (137a) is to be cut, but may be formed on both ends of the notch groove 127a (137a) in the direction in which the notch groove 127a (137a) is to be cut.

In this case, the cutting blades 170 and the V-shaped notches 127k (137k) are provided at both ends of the notch groove 127a (137a). Accordingly, even when the cutting blades 170 are moved toward any of the ends of the notch groove 127a (137a), the cutting blades 170 can be cut the coupling portion 127 (137). Therefore, when the heat exchanging members 122 (132) are mounted in the first holding base member 128 (138) and the second holding base member 121 (131) to form the corrugated heat exchanging member assembly 120 (130), it is not necessary to consider on which side of the heat exchanging member 122 (132) the V-shaped notch 127k (137k) is formed. As a result, it is possible to improve productivity relating to a mounting work.

### Fourth Embodiment

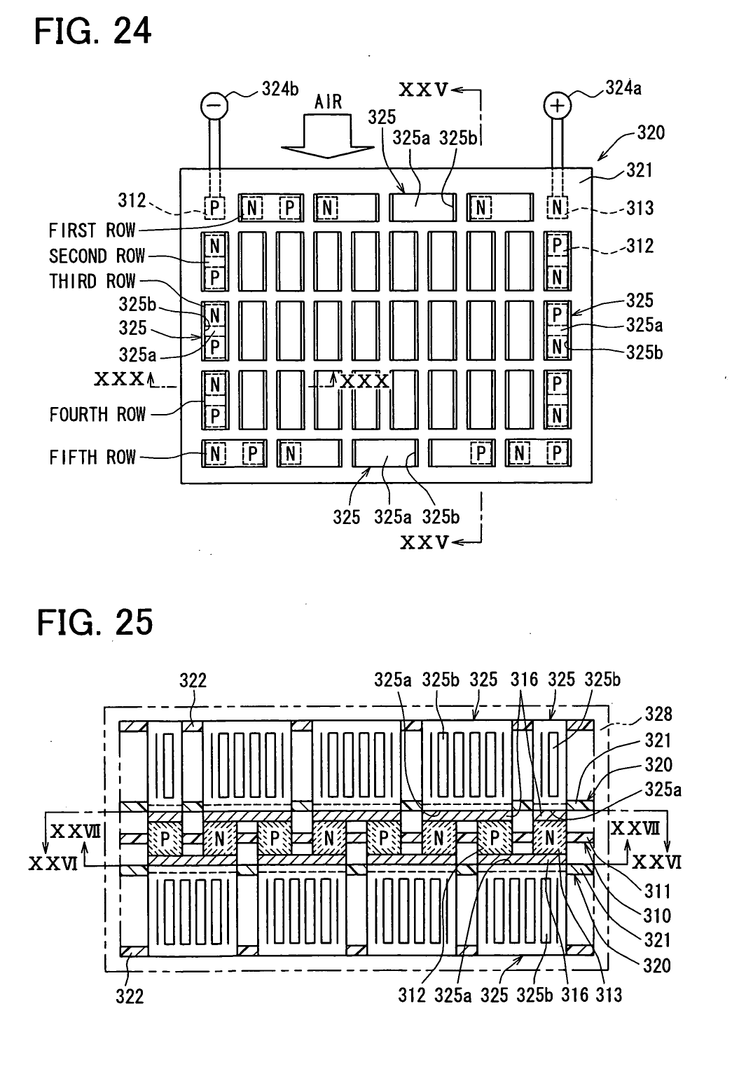

A thermoelectric transducer of the fourth embodiment of the present invention will be described on the basis of FIG. 24 to FIG. 31B.

The thermoelectric transducer of this embodiment, as shown in FIG. 24 to FIG. 30, is constructed of: a thermoelectric device substrate 310 with a plurality of P-type thermoelectric devices 312 and a plurality of N-type thermoelectric devices 313 set in an array; electrode members 316 each of which electrically connects the P-type thermoelectric device 312 with N-type thermoelectric devices 313, which are adjacent to each other, in series; a pair of heat absorbing/radiating substrates 320 each of which has a plurality of heat exchanging members 325 bonded to the electrode members 316 in such a way as to transmit heat; a pair of fixing plates 322; and a pair of case members 328.

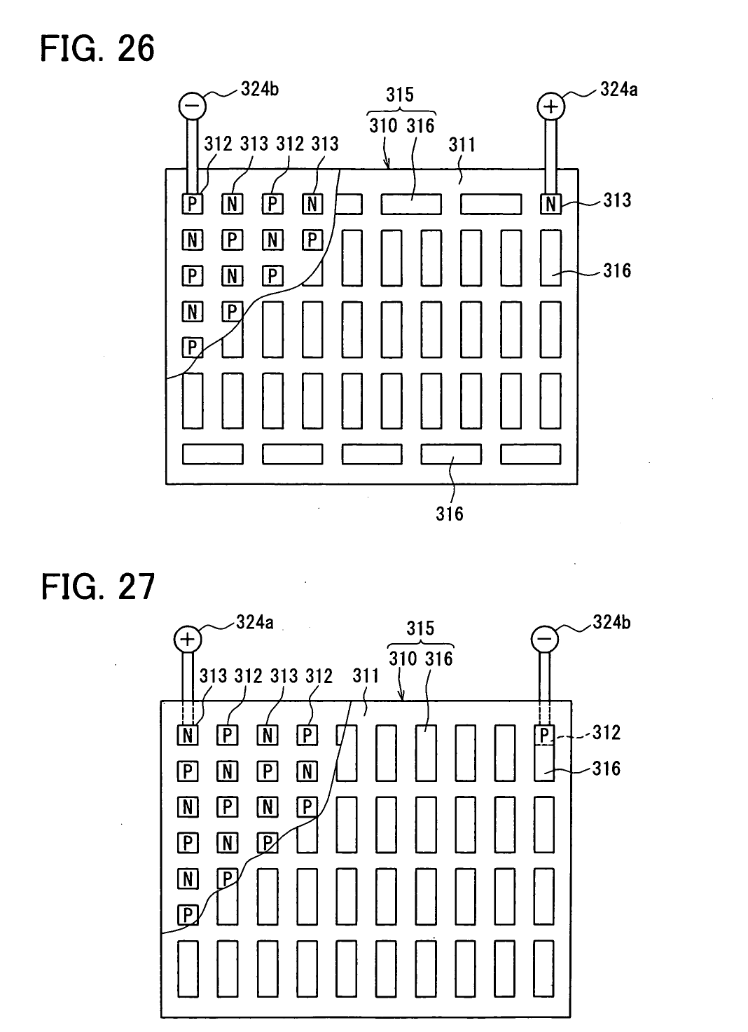

The thermoelectric device substrate 310, as shown in FIG. 26 and FIG. 27, is a thermoelectric device assembly that is integrally constructed of: a first holding plate 311 made of a plate-shaped insulating material (for example, glass epoxy, PPS resin, LCP resin, or PET resin); and a group of thermoelectric devices formed of the plurality of P-type thermoelectric devices 312 and the plurality of N-type thermoelectric devices 313 alternately arranged on the first holding plate 311.

The P-type thermoelectric device 312 is an extremely small component constructed of a P-type semiconductor made of a Bi—Te based compound, and the N-type thermoelectric device 313 is an extremely small component constructed of an N-type semiconductor made of the Bi—Te based compound. The thermoelectric device substrate 310 is integrally formed in such a way that the P-type thermoelectric devices 312 and the N-type thermoelectric devices 313 are arranged on the first holding plate 311 in a lattice pattern. At this time, the P-type thermoelectric devices 312 and the N-type thermoelectric devices 313 are formed in such a way as to protrude their top end surfaces and bottom surfaces from the first holding plate 311.

The thermoelectric devices 312, 313 arranged on a left upper end and a right upper end in the drawing have terminals 324a and 324b, respectively. A positive terminal and a negative terminal of a DC power source (not shown) are connected to these terminals 324a and 324b, respectively.

The electrode member 316 is an electrode that is formed of plate-shaped conductive metal such as copper and electrically directly connects the P-type thermoelectric device 312 with the N-type thermoelectric device 313, which are adjacent to each other, among the group of thermoelectric devices 312, 313 arranged on the thermoelectric device substrate 310. All of the electrode members 316, as shown in FIG. 26 and FIG. 27, are formed in a unified same rectangular shape to cover the end surfaces of the adjacent thermoelectric devices 312, 313.

The electrode members 316 are arranged at specified positions corresponding to the state of arrangement of the thermoelectric devices 312, 313 arranged on the thermoelectric device substrate 310, and are bonded to the thermoelectric devices 312, 313. In other words, a plurality of electrode members 316 are arranged on both end surfaces of the adjacent thermoelectric devices 312, 313. More specifically, the adjacent thermoelectric devices 312, 313 are connected to each other in such a way as to form an electrical PN junction (which will be described later) on one surface side (refer to FIG. 26) of the thermoelectric device substrate 310 and to form an electrical NP junction (which will be described later) on the other surface side (refer to FIG. 27). The electrode members 316 are soldered to the end surfaces of the thermoelectric devices 312, 313.

The electrode members 316 arranged on one surface side (refer to FIG. 26) of the thermoelectric device substrate 310 are different in the direction of arrangement between a case where the electrode members 316 are arranged on the thermoelectric devices 312, 313 adjacent to the outside end of the group of thermoelectric devices and a case where the electrode members 316 are arranged on the thermoelectric devices 312, 313 adjacent to the inside of the outside end of the group of thermoelectric devices.

In other words, as shown in FIG. 26, when the electrode members 316 are arranged on the thermoelectric devices 312, 313 adjacent to the outside end of the group of thermoelectric devices, the electrode members 316 are arranged in a direction perpendicular to the group of thermoelectric devices, whereas when the electrode members 316 are arranged on the thermoelectric devices 312, 313 adjacent to the inside of the outside end of the group of thermoelectric devices, the electrode members 316 are arranged in a direction along the group of thermoelectric devices. Here, an assembly state where the plurality of electrode members 316 are arranged on and bonded to the thermoelectric device substrate 310 is referred to as “electrode device assembly 315” as shown in FIGS. 26 and 27.

The heat absorbing/radiating substrate 320 of the heat exchanging device assembly, as shown in FIG. 24 and FIG. 25, is integrally constructed of a second holding plate 321 made of a plate-shaped insulating material (for example, glass epoxy, PPS resin, LCP resin, or PET resin) and a plurality of heat exchanging members 325.

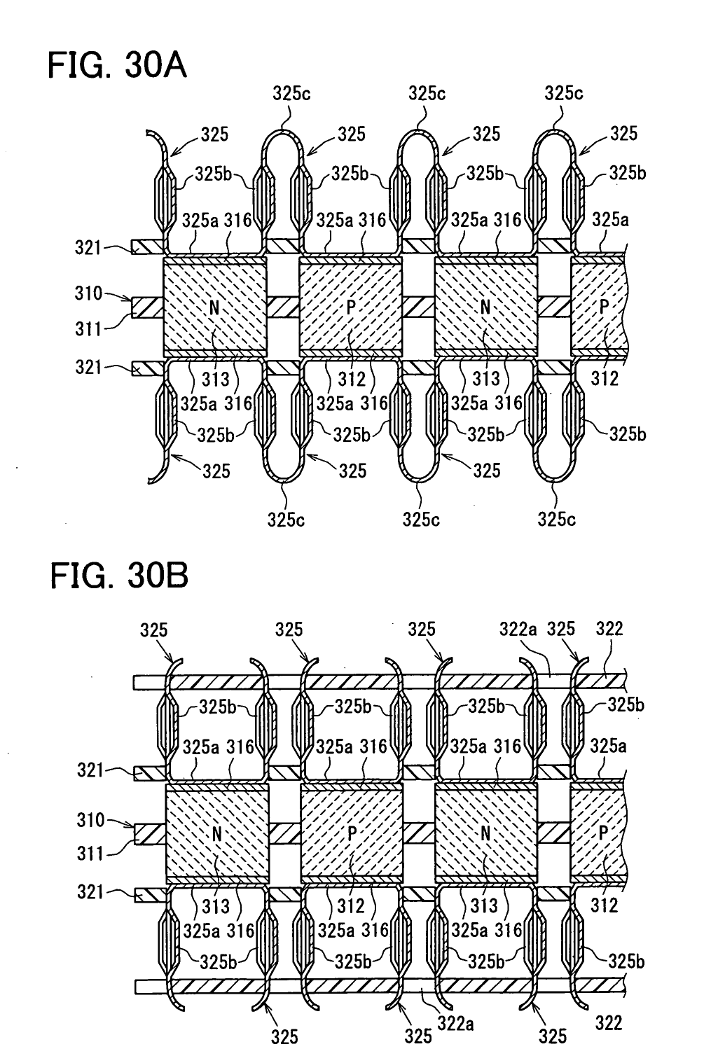

Each of the heat exchanging members 325 is formed of a thin plate of conductive material such as copper, and is formed nearly in the shape of a letter U in cross section. As shown in FIG. 30A, each of the heat exchanging members 325 has an electrode portion 325a formed in the shape of a plane at the bottom, and a heat exchanging portion 325b which is formed in the shape of a louver at a portion extended outward from the electrode portion 325a. This heat exchanging portion 325b is a fin (louver) for absorbing and radiating heat transmitted from the electrode portion 325a and is formed integrally with the electrode portion 325a by cutting and raising the thin plate.

In this embodiment, a plurality of heat exchanging members 325 are connected with each other via coupling portions 325c between the adjacent heat exchanging portions 325b. In other word, in this embodiment, the heat exchanging member 325 is not formed as a single member, but a plurality of heat exchanging members 325 are formed collectively and the electrode portions 325a are mounted on and bonded to the electrode members 316 and then the coupling portions 325c are cut off so as to electrically insulate the heat exchanging members 325 from each other.

More specifically, a plurality of heat exchanging members 325 are formed continuously in a corrugated shape (wavy shape) via the coupling portions 325c between the adjacent heat exchanging portions 325b at least along the line of the group of thermoelectric devices among the thermoelectric devices 312, 313 arranged in a lattice pattern on the thermoelectric device substrate 310. In other words, as shown in FIG. 24, a plurality of heat exchanging members 325 are coupled to each other via the coupling portions 325c for each row of the first to fifth rows.

Here, the heat exchanging members 325 arranged in the first and fifth rows are different in shape from the heat exchanging members 325 arranged in the second to fourth rows (for example, length in the direction of flow of air is different from length of electrode portion 325a).

When the heat exchanging member 325 having the electrode portion 325a and the heat exchanging portion 325b is formed in a corrugated shape (wavy shape), a method for manufacturing a plurality of heat exchanging members 325 by roll forming is extremely better, in particular, in the productivity of the process of forming the heat exchanging portion 325b, than a method for manufacturing a single heat exchanging member 325 by pressing.

Further, a roll forming method, for feeding the material by means of rollers to form the material into the heat exchanging portion 325b, the electrode portion 325a, the heat exchanging portion 325b, and the coupling portion 325c in this order, can perform a forming process at more reduced cost including equipment such as dies, as compared with a method for manufacturing the heat exchanging members 325 by a press machine provided with male and female dies. In this embodiment, the heat exchanging portion 325b is formed in the shape of a louver. However, the heat exchanging portion 325b is not limited to this shape of a louver but may be formed also in the shape of a slit or an offset.

In the heat exchanging members 325 formed for each row, their electrode portions 325a are held by the second holding plate 321 made of a plate-shaped insulating material (for example, glass epoxy, PPS resin, LCP resin, or PET resin). Specifically, as shown in FIG. 29, fitting holes 321a in which the electrode portions 325a are fitted are formed in the second holding plate 321 and the electrode portions 325a are fitted in the fitting holes 321a to integrate the heat exchanging members 325 with the second holding plate 321.

A claw portion 321b shown in FIG. 29 is a protruding claw for preventing the electrode portion 325a fitted in the fitting holes 321a from being withdrawn. Although described later in detail, as shown in FIG. 30B, the coupling portions 325c are cut off, and the end portions of the heat exchanging portions 325b having their coupling portions 325c cut off are pressed and expanded, thereby being bent and fixed to the fixing holes 322a of fixing portions of the fixing plate 322.

In other words, the end portions of the heat exchanging portions 325b having their coupling portions 325c cut off are fixed to the fixing plate 322 in such a way as to apply frictional force to peripheral portions of the fixing holes 322a. With this, the end portions of the heat exchanging portions 325b having their coupling portions 325c cut off are not withdrawn from the fixing plate 322 and the adjacent heat exchanging portions 325b are electrically insulated from each other. The fixing plate 322, just as with the second holding plate 321, is formed of a plate-shaped insulating material (for example, glass epoxy, PPS resin, LCP resin, or PET resin) and has the fixing holes 322a formed in such a way that the coupling portions 325c pass through the fixing holes 322a.

DC power inputted from the terminal 324a, as shown in FIG. 25, flows from the right upper electrode member 316 to the N-type thermoelectric device 313 and then flows in series through the adjacent P-type thermoelectric device 312 via the lower electrode member 316 and then flows from this P-type thermoelectric device 312 in series to the N-type thermoelectric device 313 via the upper electrode member 316. In other words, the electrode members 316 are connected to the thermoelectric devices 312, 313 in such a way that the DC power can flow in series to both ends of the thermoelectric devices 312, 313.

At this time, the upper electrode members 316 of FIG. 25 constructing the PN junctions are brought to a high temperature state by the Peltier effect and the lower electrode members 316 of FIG. 25 constructing the NP junctions are brought to a low temperature state. In other words, the heat exchanging portions 325b arranged on the upper side form heat radiating portions and have a high temperature state transmitted thereto and have cooling fluid brought into contact with them. Meanwhile, the heat exchanging portions 325b arranged on the lower side form heat absorbing portions and have a low temperature state transmitted thereto and have fluid to be cooled brought into contact with them.

That is, as shown in FIG. 25, air-flowing passages are formed on both sides of the thermoelectric device substrate 310 by the case member 328 and the thermoelectric device substrate 310 used as a partition wall. When air flows through the air flowing passages, heat is exchanged between the heat exchanging portions 325b and air, whereby air can be heated by the upper heat exchanging portions 325b and can be cooled by the lower heat exchanging portions 325b by means of the partition wall of the thermoelectric device substrate 310.

In this embodiment, the positive terminal of the DC power source is connected to the terminal 324a and the negative terminal of the DC power source is connected to the terminal 324b to apply the DC power to the terminal 324a. However, the positive terminal of the DC power source may be connected to the terminal 324b and the negative terminal of the DC power source may be connected to the terminal 324a to apply the DC power to the terminal 324b. However, at this time, the upper heat exchanging members 325 form the heat absorbing portions and the lower heat exchanging members 325 form the heat radiating portions.

Next, a method for manufacturing a heat exchanging member 325 and a method for assembling a thermoelectric transducer will be described. First, a plurality of heat exchanging members 325 is formed by a roll forming method. That is, a conductive material is fed into a nip formed by a pair of male and female rollers to form a plurality of heat exchanging members 325 each including the heat exchanging portion 325b, the electrode portion 325a, the heat exchanging portion 325b, and the coupling portion 325c formed continuously in this order in a corrugated shape.

In contrast, the plurality of P-type thermoelectric devices 312 and the plurality of N-type thermoelectric devices 313, as shown in FIG. 26 and FIG. 27, are alternately arranged nearly in a lattice pattern in the substrate holes formed in the first holding plate 311 to construct the thermoelectric device substrate 310. At this time, the thermoelectric device substrate 310 may be manufactured by the use of a mounter of a manufacturing apparatus for mounting semiconductors and electronic components on a control substrate.

Then, a plurality of electrode members 316 each formed in the shape of a plane are picked up and placed on the end surfaces of the thermoelectric devices 312, 313 arranged adjacently to the thermoelectric device substrate 310, as shown in FIG. 26 and FIG. 27. Then, the electrode members 316 are soldered to the thermoelectric devices 312, 313, so that the electrode device assembly 315 is formed.

Here, this electrode device assembly 315 is formed for each surface. When the other surface is formed, the thermoelectric device substrate 310 is turned over and then the electrode members 316 are soldered to the thermoelectric devices 312, 313 on the other surface. When paste solder or the like is applied thinly uniformly in advance to the end surfaces of the thermoelectric devices 312, 313 by screen printing and then a soldering process is performed, the soldering process can be easily performed.

The plurality of heat exchanging members 325 formed in the corrugated shape are picked and fitted into the fitting holes 321a formed in the second holding plate 321 for each row to arrange a plurality of rows of heat exchanging members 325 in the second holding plate 321 to form the heat absorbing/radiating substrate 320.

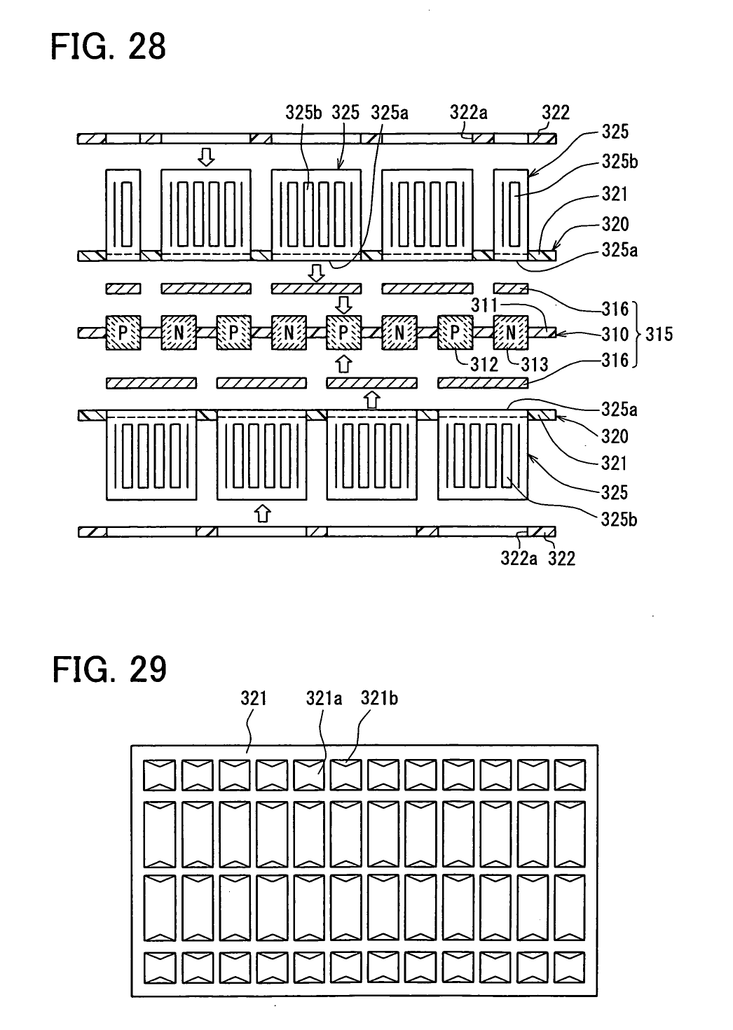

Specifically, a pair of heat absorbing/radiating substrate 320 on a heat radiating side and heat absorbing/radiating substrate 320 on a heat absorbing side are formed. The electrode device assembly 315 is sandwiched between and combined with the heat absorbing/radiating substrate 320 on the heat radiating side and the heat absorbing/radiating substrate 320 on the heat absorbing side as shown in FIG. 28. The respective electrode devices 316 are made to abut against and soldered in unison to the respective electrode portions 325a.

Here, the forming of this soldered assembly is performed for each surface. When the forming of the solder assembly is performed for the other surface, the thermoelectric device substrate 310 is turned over and then the electrode members 316 are soldered to the electrode portions 325a on the other surface. Then, the coupling portions 325c between the adjacent heat exchanging portions 325b of the heat exchanging members 325 of the soldered assembly, which is formed by soldering the electrode device assembly 315 to the heat exchanging device assembly 320, are cut off. Then, the end portions of the heat exchanging portions 325b having their coupling portions 325c cut off are bent, thereby being fixed to the peripheral portion of the fixing holes 322a of the fixing plate 322, so that a fixing body for the heat exchanging device is formed.

This fixing body will be described on the basis of FIG. 30A and FIG. 30B. FIG. 30A is a partial sectional view when the above-described soldered assembly is formed and shows a state where the heat exchanging members 325 are electrically connected to each other via the coupling portions 325c. Then, as shown in FIG. 30B, the coupling portions 325c are cut off and the end portions of the heat exchanging portions 325b having their coupling portions 325c cut off are pressed and bent to the fixing holes 322a to form the fixing body.

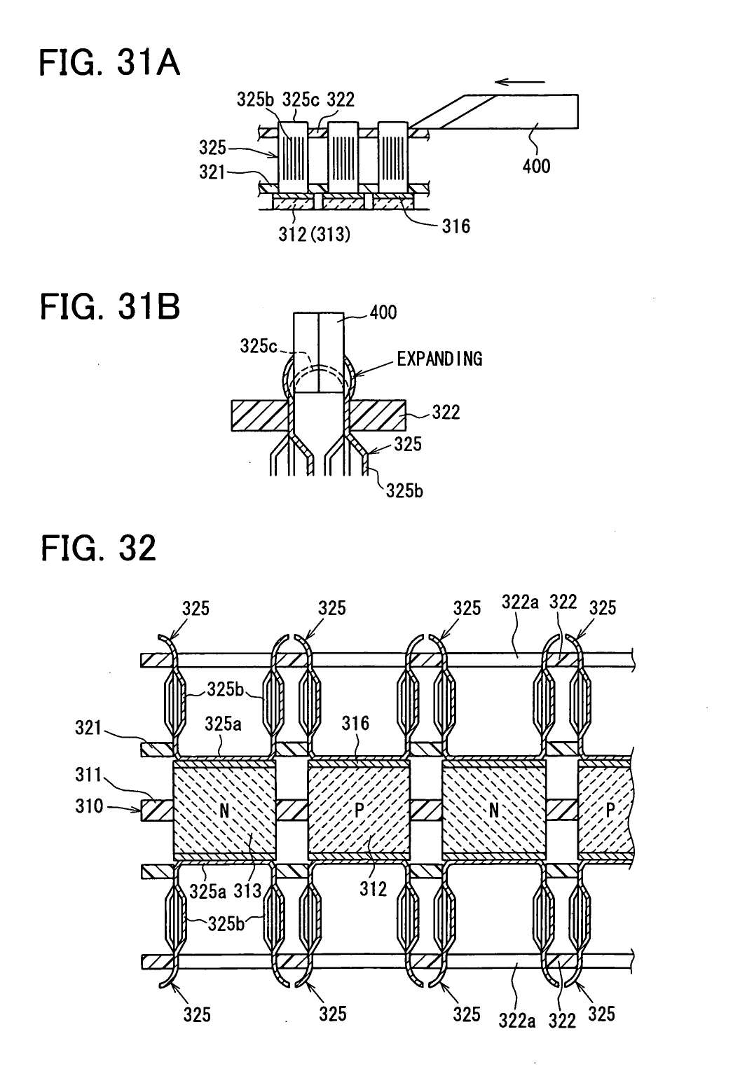

Further specifically, as shown in FIG. 31A and FIG. 31B, the coupling portions 325c are fitted in the fixing holes 322a formed in the fixing plate 322. Then, a cutting and bending jig 400 having a cutting edge formed on the tip is moved in a direction shown by arrow in FIG. 31A, thereby the coupling portions 325c are cut off. At the same time, the cut end portions are pressed and expanded by the cutting and bending jig 400, thereby being pressed and bent onto the fixing plate 322.

In other words, the cut end portions of the coupling portions 325c are deformed in such a way as to apply frictional forces to the peripheral portions of the fixing holes 322a. With this, the cut end portions are fixed to the fixing plate 322 and hence the adjacent heat exchanging members 325 are electrically insulated from each other.

In this embodiment, as shown in FIG. 31A and FIG. 31B, the fixing body for the heat exchanging device is formed by the use of cutting and bending jig. However, it is also recommendable to cut off the coupling portions 325c by the laser machining of applying laser light or by sliding a cutter in the direction shown by arrow and then by pressing and bending the cut end portions by another jig.

Then, the case members 328 are combined with the second holding plate 321 to form air passages on the upper side and the lower side, thereby the heat radiating part and the heat absorbing part are formed on the upper side and the lower side. By flowing air through these parts, cold air and hot air can be obtained. The thermoelectric transducer like this can be applied to an apparatus for cooling a heat generating component such as semiconductor and electric component and for heating a heating unit.

According to a manufacturing method including the processes described above, first, a plurality of heat exchanging members 325 are formed continuously. Hence, it is possible to reduce the number of man-hours required to form the heat exchanging members 325 as compared with a conventional manufacturing method for manufacturing a single heat exchanging member by pressing.

Moreover, the plurality of heat exchanging members 325 are formed continuously in the corrugated shape and then are soldered to one end surfaces of the electrode members 316. Hence, the plurality of heat exchanging members 325 can be formed by roll forming. Therefore, this can reduce the number of man-hours required to form and assemble the heat exchanging members 325 and hence can reduce the number of manufacturing man-hours.

According to the thermoelectric transducer in accordance with the fourth embodiment, portions close to soldered portions of the electrode portions 325a are held by the second holding plate 321 and other end sides opposite to the electrode portion 325a are fixed by the fixing plate 322, and the adjacent heat exchanging members 325 are electrically insulated from each other. Hence, even if the stresses caused when the heat exchanging members 325 are formed remain, the other end sides of the heat exchanging members 325 are not withdrawn from the fixing plate 322. With this, the adjacent heat exchanging members 325 are prevented from being brought into electrical contact with each other.

Moreover, when the other end sides opposite to the electrode portions 325a are fixed to the fixing plate 322, the other end sides of the heat exchanging portions 325a are fixed to the fixing holes 322a in such a way as to apply frictional forces to the peripheral portions of the fixing holes 322a. Hence, the other end sides of the heat exchanging members 325 are not withdrawn from the fixing plate 322. Furthermore, although there is a method for fixing the other end sides of the heat exchanging members 325 to the fixing plate 322 by an adhesive, the other end sides of the heat exchanging members 325 can be fixed to the fixing plate 322 with reliability without using the method using the adhesive. In addition, this method can reduce the steps required to assemble the heat absorbing/radiating substrates 320, as compared with the method using an adhesive.

Furthermore, a plurality of heat exchanging members 325 are formed each of which has the heat exchanging portion 325b, the electrode portion 325a, the heat exchanging portion 325b, and the coupling portion 325c formed continuously in this order in the corrugated shape. Hence, the assembling steps required to form the heat exchanging portions 325 and the assembling steps required to mount the heat exchanging portions 325 on the second holding plate 321 can be reduced, as compared with the case of forming the heat exchanging portions 325 as single members. This can reduce the number of manufacturing steps.

Still further, the thermoelectric transducer of the present embodiment includes: a plurality of heat exchanging-members 325 each having the electrode portion 325a, the heat exchanging portion 325b, the coupling portion 325c, and the heat exchanging portion 325b formed in this order continuously in the corrugated shape; and the second holding plate 321 for holding the plurality of heat exchanging members 325. Further, the electrode portions 325a of the plurality of heat exchanging members 325 are held on the second holding plate 321 in the specified state of arrangement corresponding to the state of arrangement of the electrode members 316. With this, steps for forming the heat exchanging members 325 can be reduced, and the heat exchanging members 325 can be easily mounted on the second holding plate 321.

Still further, in the present embodiment, the plurality of the heat exchanging members 325 are formed by continuously performing the cutting of the coupling portions 325c and the pressing and expanding of the end portions of the heat exchanging portions 325b having their coupling portions 325c cut off so as to fix the cut off portion to the fixing plate 322. Hence, the end portions of the heat exchanging portions 325b having their coupling portions 325c cut off can be surely fixed to the fixing plate 322 and the assembling performance can be enhanced.

### Fifth Embodiment

In the fourth embodiment, the fixing holes 322a are formed in the fixing plate 322 in such a way that the heat exchanging members 325 pass through the fixing holes 322a and the end portions of the heat exchanging portions 325b having their coupling portions 325c cut off are pressed and bent in such a way as to expand to the electrode portions 325a, thereby being fixed to the peripheral portion of the fixing holes 322a. However, the method for fixing the heat exchanging members 325 to the fixing holes 322a is not limited to this. For example, the fixing holes 322a are formed on a side opposite to one end surfaces of the electrode portions 325a and the end portions of the heat exchanging portions 325b having their coupling portions 325c cut off are pressed and bent in such a way as to expand to the coupling portions 325c, thereby being fixed to the fixing holes 322a.

Specifically, as shown in FIG. 32, the fixing holes 322a are formed on the side opposite to the one end surfaces of the electrode portions 325a of the heat exchanging members 325 and the coupling portions 325c are cut off and the cut end portions are pressed and bent by a bending jig, thereby being fixed to the peripheral portion of the fixing holes 322a in the fixing plate 322.

That is, the end portions of the heat exchanging members 325 having their coupling portions 325c cut off are fixed to the fixing plate 312 by pressing and bending. With this, the cut end portions apply frictional forces to the peripheral portions of the fixing holes 322a of the fixing plate 322, thereby the cut end portions are surely fixed to the fixing plate 322 having the fixing holes 322a. Hence, it can prevent the adjacent heat exchanging members 325 from being brought into electric contact with each other.

When the fixing holes 322a are formed in such a way that their opening areas are as small as or a little smaller than the one end surfaces of the electrode portions 325a, respectively, the cur end portions can apply larger frictional forces to the peripheral portions of the fixing holes 322a I the fixing plate 322.

### Sixth Embodiment

In the above-described embodiments, the heat exchanging members 325 are formed by forming the plurality of heat exchanging members continuously in the corrugated shape (wavy shape) with the coupling portions 325c interposed between the adjacent heat exchange portions 325b and by cutting the coupling portions 325c at the time of assembling. However, the heat exchanging member 325 can be as a single member having the electrode portion 325a and the heat exchanging portion 325b.

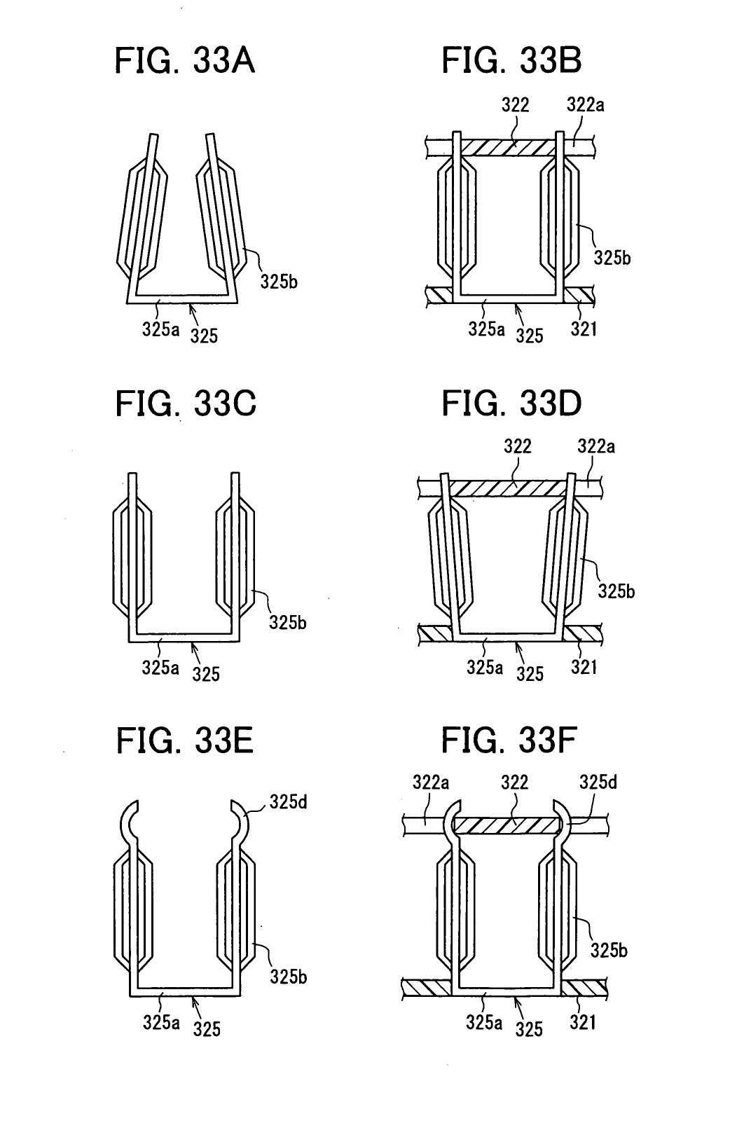

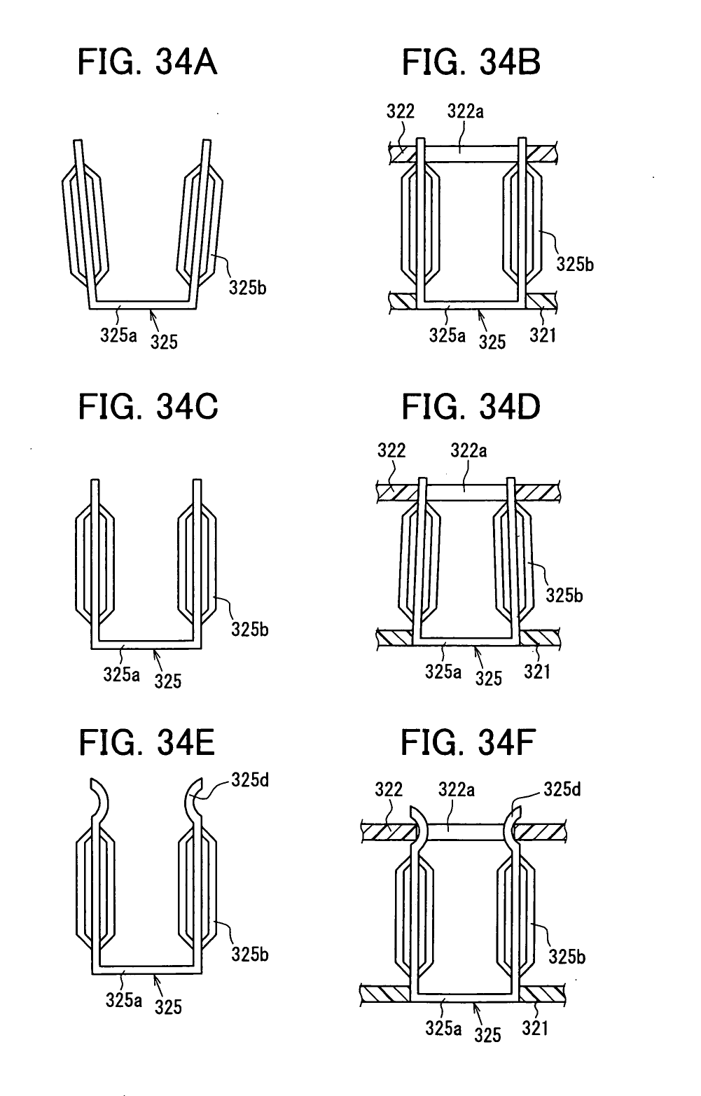

Specifically, as shown in FIG. 33A to FIG. 33F and FIG. 34A to FIG. 34F, the heat exchanging members 325 of various shapes are formed in such a way as to be fixed to the fixing plate 312. In FIGS. 33B, 33D, and 33F, the fixing holes 322a of the fixing plate 322 are formed between the adjacent heat exchanging portions 325b. In FIGS. 34B, 34D, and 34F, the fixing holes 322a of the fixing plate 322 are formed opposite to one end surfaces of the electrode portion 325a.

Specifically, FIG. 33A shows a shape before fixing the heat exchanging member 325 to the second holding plate 321 and the fixing plate 322, and FIG. 33B shows a shape after fixing the heat exchanging member 325 to the second holding plate 321 and the fixing plate 322. The heat exchanging member 325 shown in FIG. 33A such that the distance between the heat exchanging portions 325b is gradually narrowed toward the end portions, that is, nearly in the shape of a letter U in cross section. The end portions of the heat exchanging portions 325b are expanded in such a way as to apply frictional forces to the peripheral portion of the fixing hole 322a of the fixing plate 322 as shown in FIG. 33B.

According to this, when the end portions of the heat exchanging portions 325b are fitted in the fixing hole 322a, frictional forces are applied between their end portions and the peripheral portion of the fixing hole 322a of the fixing plate 322. This can prevent the adjacent heat exchanging portions 325b from being brought into contact with each other.

Moreover, as shown in FIGS. 33C and 33D, the heat exchanging member 325 is formed nearly in the cross-sectional shape of a letter U such that one end surface of the electrode portion 325a is perpendicular to the end portions of the heat exchanging portions 325b, and the fixing hole 322a of the fixing plate 322 is formed in an area smaller than that in FIGS. 33A and 33B. In this manner, the heat exchanging member 325 is fixed to the fixing plate 322 in such a way that the distance between the heat exchanging portions 325b are gradually expanded toward their end portions as shown in FIG. 33D.

Accordingly, when the end portions of the heat exchanging portions 325b are fitted in the fixing holes 322a, frictional forces are applied between the end portions of the heat exchanging portions 325b and the peripheral portions of the fixing holes 322a. This can prevent the adjacent heat exchanging portions 325b from being brought into contact with each other.

Moreover, as shown in FIGS. 33E and 33F, the end portion of the heat exchanging portion 325b is formed to have a fitting portion 325d such that the fitting potion 325d formed at the end portion of the heat exchanging portions 325b is fitted with the peripheral portion of the fixing hole 322a.

Furthermore, as shown in FIGS. 34A and 34B, the heat exchanging portions 325b are formed in a shape such that the distance between the heat exchanging portions 325b are gradually expanded toward their end portions, that is, nearly in the shape of a letter U in cross section. The heat exchanging member 325 is arranged in such a way that the end portions of the heat exchanging portions 325b apply frictional forces to the peripheral portion of the fixing hole 322a that is opened in the fixing plate 322 to opposite to the electrode portion 325a. Accordingly, when the end portions of the heat exchanging portions 325b are fitted with the peripheral portion of the fixing hole 322, the frictional forces are generated between the end portions and the peripheral portions of the fixing holes 322a. This can prevent the adjacent heat exchanging portions 325b from being brought into contact with each other.

Still further, as shown in FIGS. 34C and 34D, the heat exchanging member 325 is formed nearly in the cross-sectional shape of a letter U such that one end surface of the electrode portion 325a is perpendicular to the end portions of the heat exchanging portions 325b, and the fixing hole 322a of the fixing plate 322 is formed in an area smaller than that in FIGS. 34A and 34B. In this manner, the heat exchanging member 325 is fixed to the fixing plate 322 in such a way that the distance between the heat exchanging portions 325b are gradually narrowed toward their end portions. According to this, when the end portions of the heat exchanging portions 325b are fitted with the peripheral portion of the fixing hole 322a, frictional forces are generated between the end portions of the heat exchanging portions 325b and the peripheral portion of the fixing hole 322a. This can prevent the adjacent heat exchanging portions 325b from being brought into contact with each other.

Moreover, as shown in FIGS. 34E and 34F, the end portion of the heat exchanging portion 325b can be formed to have a fitting portion 325d such that the fitting potion 325d formed at the end portion of the heat exchanging portions 325b is fitted with the peripheral portion of the fixing hole 322a.

### Other Embodiments

In the above-described fourth to sixth embodiments, the heat exchanging member 325 is fitted in the fixing hole 322a in such a way that the end portions of the heat exchanging portions 325b apply frictional forces to the peripheral portion of the fixing hole 322a of the fixing plate 322. Alternatively, the heat exchanging member 325 is fitted in the fixing hole 322a by forming the fitting portion 325d at the end portion of the heat exchanging portion 325b. However, the method for fixing the heat exchanging member 325 into the fixing hole 322a of the fixing plate 322 is not limited these. For example, end portions of the heat exchanging portions 325b may be fixed to the fixing hole 322a by an adhesive.

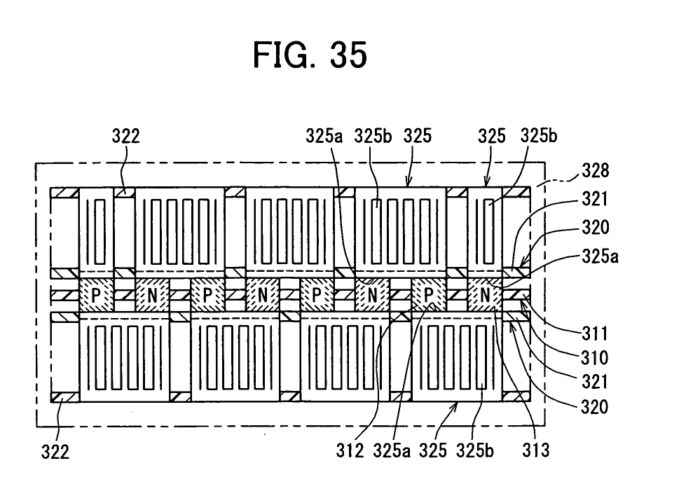

Furthermore, in the above-described fourth to sixth embodiments, the present invention is applied to the thermoelectric transducer of the type in which the electrode portions 325a of the heat exchanging members 325 are bonded to the thermoelectric devices 312, 313 via separate electrode members 316. However, the present invention is not limited to this but, specifically, as shown in FIG. 35, may be applied to a thermoelectric transducer of the type in which the electrode portions 325a are directly bonded to the adjacent thermoelectric devices 312, 313 of the heat exchanging members 325 without providing the electrode members 316.

While the invention has been described with reference to preferred embodiments thereof, it is to be understood that the invention is not limited to the preferred embodiments and constructions. The invention is intended to cover various modification and equivalent arrangements. In addition, while the various elements of the preferred embodiments are shown in various combinations and configurations, which are preferred, other combinations and configuration, including more, less or only a single element, are also within the spirit and scope of the invention.

What is claimed is:

1. A thermoelectric transducer comprising:
a thermoelectric device substrate;
a group of thermoelectric devices including a plurality of P-type thermoelectric devices and a plurality of N-type thermoelectric devices alternately arranged on the thermoelectric device substrate;
electrode members made of a conductive material and for electrically connecting the P-type thermoelectric devices and the N-type thermoelectric devices arranged adjacent to each other on the thermoelectric device substrate; and
heat exchanging members including electrode portions connected to the electrode members to transmit heat thereto, and heat exchanging portions for absorbing and radiating the heat transmitted from the electrode portions, wherein:
the adjacent P-type and N-type thermoelectric devices are connected to each other in series via the electrode members;
among the electrode portions and the heat exchanging portions in the heat exchanging members, at least a plurality of electrode portions and a plurality of heat exchanging portions are formed continuously in a corrugated shape to couple the plurality of electrode members to each other along at least the group of thermoelectric devices; and
the adjacent heat exchanging members are provided to be electrically insulated from each other.

2. The thermoelectric transducer as in claim 1, wherein:
in the heat exchanging member, a plurality of adjacent heat exchanging portions are coupled continuously in a corrugated shape via coupling portions, and the adjacent heat exchanging portions are electrically insulated from each other by cutting the coupling portions.

3. The thermoelectric transducer as in claim 2,
wherein the adjacent heat exchanging portions are electrically insulated from each other by cutting the coupling portions of the heat exchanging member using one of a laser, a cutter, a cutting jig, a punching and an etching.

4. The thermoelectric transducer as in claim 2, further comprising a fixing member having a flat plate shape and made of an insulating material,
wherein the fixing member fixes end portions of the heat exchanging portions, from which the coupling portions are cut off.

5. The thermoelectric transducer as in claim 1, further comprising an insulating substrate having a flat plate shape and made of an insulating material,
wherein the electrode portions of the heat exchanging member are fitted into a plurality of fitting holes formed at intervals in the insulating substrate.

6. The thermoelectric transducer as in claim 1,
wherein the plurality of the heat exchanging portions are provided continuously in the corrugated shape via coupling portions each having an arch portion, the adjacent heat exchanging portions are electrically insulated from each other by cutting the coupling portions, and a corner of the arch portion of the cut coupling portion has a cut-raised portion.

7. The thermoelectric transducer as in claim 6, further comprising:
a first holding base member having first fitting holes into which the coupling portions are inserted; and
a second holding base member having second fitting holes into which the electrode portions are fitted;
wherein the coupling portions are inserted into the first fitting holes and the electrode portions are fitted into the second fitting holes to form a corrugated heat exchanging member assembly.

8. The thermoelectric transducer as in claim 6,
wherein the arch portion of the cut coupling portion is cut and raised in such a way as to have a width Wf larger than a width Wa of the heat exchanging portion.

9. A method of manufacturing a thermoelectric transducer, comprising the steps of:
forming a plurality of heat exchanging members, each of which includes a first heat exchanging portion, an electrode portion, a second heat exchanging portion and a coupling portion in this order, continuously in a corrugated shape by using a conductive material;
forming a thermoelectric device substrate on which a plurality of P-type thermoelectric devices and a plurality of N-type thermoelectric devices are alternately arranged substantially in a lattice pattern to arrange a group of thermoelectric devices;
placing electrode members on end surfaces of the P-type thermoelectric devices and the N-type thermoelectric devices, which are arranged adjacent to each other on the thermoelectric device substrate, and then bonding the electrode members to the P-type thermoelectric devices and the electrode members to the N-type thermoelectric devices;
placing a plurality of rows of the electrode portions of the plurality of heat exchanging members formed in the corrugated shape in the step of forming the heat exchanging members on one end surfaces of the electrode members along at least the group of thermoelectric devices, and then bonding the electrode members to the electrode portions; and
cutting the coupling portions formed between the adjacent heat exchanging portions of the plurality of heat exchanging members having their electrode portions bonded to the electrode members in the step of bonding the heat exchanging member, to thereby electrically insulate the heat exchanging members from each other.

10. The method of manufacturing a thermoelectric transducer as in claim 9, further comprising the step of fixing end portions of the heat exchanging portions, from which the coupling portions are cut off, after the cutting step by using a fixing member having a flat plate shape and made of an insulating material.

11. The method of manufacturing a thermoelectric transducer as in claim 9, further comprising a provisionally assembling step in which the electrode portions are fitted or pressed in fitting holes formed at intervals in an insulating substrate shaped like a flat plate and made of an insulating material after the step of forming the heat exchanging members.

12. The method of manufacturing a thermoelectric transducer as in claim 9, wherein in the step of forming the heat exchanging members, a plurality of the heat exchanging members are formed in a corrugated shape by roller process.

13. The method of manufacturing a thermoelectric transducer as in claim 9, wherein in the cutting step, the coupling portions are cut by using any one of a laser, a cutter, a cutting jig, a punching and an etching.

14. The method of manufacturing a thermoelectric transducer as in claim 9,
wherein the cutting step includes a step of forming a notch groove on the coupling portion in a direction in which the coupling portion is to be cut, and a step of cutting and raising the coupling portion from a starting point at an end of the coupling portion, to thereby form a cut-raised portion.

15. The method of manufacturing a thermoelectric transducer as in claim 14,
wherein after the step of forming the cut-raised portion, a cutting blade is moved relatively toward a cut raised side of the coupling portion.

16. The method of manufacturing a thermoelectric transducer as in claim 14, wherein:
in the step of forming the cut-raised portion, first fitting holes for inserting therein the coupling portions are formed in a first holding base member for holding the coupling portions;
the coupling portions are inserted into the first fitting holes, thereby being held in the first holding base member; and
the cutting blades are moved relatively toward arch portions of the coupling portions protruding from the first fitting holes, to thereby cut and raise the arch portions in a direction of width of the first fitting holes.

17. The method of manufacturing a thermoelectric transducer as in claim 16, further comprising
forming second fitting holes for fitting the electrode portions, in a second holding base member for holding the electrode portions,
wherein the cutting blades are moved relatively toward the cut raised sides of the coupling portions after the electrode portions are fitted into the second fitting holes.

18. The method of manufacturing a thermoelectric transducer as in claim 14, further comprising the steps of:
forming first fitting holes, for inserting therein the coupling portions, in a first holding base member for holding the coupling portions;
forming second fitting holes, for fitting the electrode portions, in a second holding base member for holding the electrode portions; and
inserting the coupling portions into the first fitting holes and fitting the electrode portions into the second fitting holes, so as to form a corrugated heat exchanging member assembly.

19. The method of manufacturing a thermoelectric transducer as in claim 15,
wherein in the cutting step, the cutting blades are moved relatively to thereby divide and raise arch portions of the coupling portions.

20. A method of manufacturing a corrugated fin for forming a plurality of heat exchanging members each of which includes a heat exchanging portion, an electrode portion, a heat exchanging portion, and a coupling portion in this order, continuously in a corrugated shape by using a fin material shaped like a belt and made of a conductive material, the method comprising the steps of:
forming a notch groove on the coupling portion in a direction in which the coupling portion is to be cut;
bending the fin material at portions between the electrode portion, the heat exchanging portion, and the coupling portion to form them in the corrugated shape;
forming a louver in the heat exchanging portion between a crest and a trough in the corrugated shape; and
forming a cut-raised portion for guiding a cutting blade from a starting point at an end of the notch groove.

21. A thermoelectric transducer comprising:
a thermoelectric device assembly that includes a plurality of P-type thermoelectric devices, a plurality of N-type thermoelectric devices, and a first holding plate for holding these plurality of thermoelectric devices, the plurality of thermoelectric devices being arranged in a predetermined arrangement on the first holding plate;
a pair of heat exchanging device assemblies each of which includes a plurality of heat exchanging devices provided in correspondence with the plurality of thermoelectric devices, and a second holding plate for holding these plurality of heat exchanging devices, the plurality of heat exchanging devices being held in an arrangement corresponding with the predetermined arrangement of the thermoelectric devices; and
a fixing plate for fixing the heat exchanging devices; wherein:
the respective thermoelectric devices are connected electrically to the respective heat exchanging devices in a state where the thermoelectric device assembly is located between the pair of heat exchanging device assemblies;
each of the heat exchanging devices has an electrode portion connected to the thermoelectric device to transmit heat, and a heat exchanging portion for exchanging heat transmitted from the electrode portion;
the heat exchanging device assembly has a first portion close to a connection portion of the electrode portion, which is held by the second holding plate, and a second portion opposite to the electrode portion, which is fixed to the fixing plate; and
adjacent heat exchanging devices in each heat exchanging device assembly are electrically insulated from each other.

22. The thermoelectric transducer according to claim 21, wherein:
the thermoelectric device assembly further includes a plurality of electrode devices for electrically connecting the plurality of P-type thermoelectric devices directly to the plurality of N-type thermoelectric devices; and
the electrode portions of the heat exchanging devices are connected to the thermoelectric devices via the electrode devices to transmit heat.

23. The thermoelectric transducer according to claim 21, wherein:
the heat exchanging portion of the heat exchanging device extends outward from the electrode portion to have an extended end portion; and
the extended end portion of the heat exchanging portion is fixed to a fixing portion of the fixing plate to generate a frictional force between the extended end portion and the fixing portion of the fixing plate.

24. The thermoelectric transducer according to claim 21, wherein:
in each of the heat exchanging device assemblies, the plurality of heat exchanging devices are coupled continuously in a corrugated shape via coupling portions, and the adjacent heat exchanging portions are electrically insulated from each other by cutting the coupling portion.

25. The thermoelectric transducer according to claim 23, wherein the end portion of the heat exchanging device, opposite to the electrode portion, is gradually expanded or narrowed from the electrode portion toward a tip end of the end portion, and is fixed to the fixing plate.

26. The thermoelectric transducer according to claim 25, wherein the end portion of the heat exchanging device, opposite to the electrode portion is gradually expanded toward the tip end, and the fixing plate has a fixing portion formed adjacent to the coupling portion before being cut.

27. The thermoelectric transducer according to claim 25, wherein the end portion of the heat exchanging device, opposite to the electrode portion is gradually narrowed toward the tip end, and the fixing plate has a fixing portion formed at a portion opposite to the electrode portion.

28. The thermoelectric transducer according to claim 21, wherein the heat exchanging device assembly has an end portion opposite to the electrode portion of the heat exchanging device, and the end portion is fitted with a fixing portion of the fixing plate.

29. The thermoelectric transducer according to claim 21, wherein the heat exchanging device assembly has an end portion opposite to the electrode portion of the heat exchanging device, and the end portion is adhered to a fixing portion of the fixing plate.

30. A method of manufacturing a thermoelectric transducer, comprising the step of:
forming a plurality of heat exchanging devices each of which includes a first heat exchanging portion, an electrode portion, a second heat exchanging portion and a coupling portion in this order, continuously in a corrugated shape by using a conductive material;
forming a thermoelectric device assembly in which a plurality of P-type thermoelectric devices and a plurality of N-type thermoelectric devices are arranged in a predetermined arrangement to be held by a first holding plate;
forming a pair of heat exchanging device assemblies each of which includes the heat exchanging devices provided in correspondence with the plurality of thermoelectric devices, and a second holding plate for holding these plurality of heat exchanging devices, the plurality of heat exchanging devices being held in an arrangement corresponding with the predetermined arrangement of the thermoelectric devices; and
connecting the respective thermoelectric devices to the respective heat exchanging devices in a state where the thermoelectric device assembly is located between the pair of heat exchanging device assemblies;
cutting the coupling portion formed between each of adjacent heat exchanging portions to have a cut portion; and
fixing the cut portion to a fixing plate.

31. The method according to claim 30, wherein:
the step of forming the thermoelectric device assembly includes a step of forming a plurality of electrode devices for electrically connecting the P-type thermoelectric devices and the N-type thermoelectric devices,
in the connecting step, electrode portions of the heat exchanging devices are connected to the thermoelectric devices via the electrode devices.

32. The method according to claim 30, wherein the cut portion of the heat exchanging portion is fixed to a fixing portion of the fixing plate to have a friction force with the fixing portion.

33. The method according to claim 30, wherein,
in the cutting step, the cut portion is bent and expended at its ends to be fixed to the fixing plate.

34. The method according to claim 30, wherein the cutting step is performed after the coupling portion is inserted into a fixing portion of the fixing plate.
